(19) United States
(12) Patent Application Publication
(10) Pub. No.: US 2024/0298465 A1
(43) Pub. Date: Sep. 5, 2024

(54) METHOD OF MANUFACTURING LIGHT EMITTING DEVICE

(71) Applicant: CANON KABUSHIKI KAISHA, Tokyo (JP)

(72) Inventor: JUN YAMAGUCHI, Kanagawa (JP)

(21) Appl. No.: 18/581,475

(22) Filed: Feb. 20, 2024

(30) Foreign Application Priority Data
Mar. 3, 2023 (JP) 2023-033074

(51) Int. Cl. H10K 59/12; H10K 59/131; H10K 71/00; H10K 71/20

(52) U.S. Cl. CPC H10K 59/1201; H10K 59/131; H10K 71/233; H10K 71/621

(57) ABSTRACT

A method of manufacturing a light emitting device, the method including forming a resist layer on the first insulating layer so as to expose a part of the first insulating layer in a region, the second electrode layer being on an element constituting layer including a light-emitting layer that is arranged on a first electrode, removing the first insulating layer, the second electrode layer, and the element constituting layer in the region, removing the resist layer after removing the first insulating layer, the second electrode layer, and the element constituting layer, and forming a side wall including an insulating material, which covers side surfaces of the first insulating layer, the second electrode layer, and the element constituting layer, after removing the resist layer.

### BACKGROUND OF THE INVENTION

### Field of the Invention

The present invention relates to a method of manufacturing a light emitting device.

### Description of the Related Art

An electroluminescent device is a device formed by arraying, on a base or a substrate, a plurality of light emitting elements in a line or a matrix. Such a light emitting device is capable of multicolor display when light emitting elements whose light emission colors are different from each other, for example, light emitting elements whose light emission colors are red, green, and blue, respectively, are arranged such that a set of pixels is formed by combining the light emitting elements each including at least one light emitting element of each color.

The light emitting element forming the light emitting device includes a pair of electrodes, and a light emitting layer arranged between the pair of electrodes. Here, the light emission color of the light emitting element can be changed by appropriately selecting the light emission material forming the light emitting layer.

In recent years, as a general process for manufacturing an organic light emitting element using an organic light emitting diode (OLED), a vacuum deposition process using a high-precision mask is known. The vacuum deposition process includes a deposition process of an element constituting layer by a vacuum deposition method using a high-precision mask, and a deposition process of an upper electrode layer by a vacuum sputtering deposition using a mask. However, in the vacuum deposition process using a high-precision mask, due to alignment of the mask, the thickness of the mask, bending of the mask, and the like, the film thickness of the formed element constituting layer may tilt (vary). The region of the element constituting layer where the film thickness tilts becomes a region unusable as a constituent member of the organic light emitting element, that is, a blurring region. Therefore, in the vacuum deposition process using a high-precision mask, it is difficult to reduce a frame region (a region outside a display area formed by a group of light emitting pixels and extending up to the substrate end).

To solve this problem, Japanese Patent Laid-Open No. 2016-21380 proposes a technique of patterning, by photolithography, a stacked body stacked with an element constituting layer in place of the vacuum deposition process using a high-precision mask. By using photolithography, the formable definition dramatically improves, and it is possible to minimize the blurring region generated at the film end of the patterned element constituting layer. On the other hand, since the end face or surface of the film, which is to be the element constituting layer, is exposed to a liquid or external environment during patterning by lithography, this can cause deterioration of the device characteristics of the light emitting element such as the luminance, driving voltage, light emission life, or the like. Patent literature 1 discloses a technique of causing an electrode material on an element constituting layer to function as a protection layer, thereby patterning the element constituting layer by photolithography without exposing the element constituting layer to a liquid or external environment.

However, in the technique disclosed in Japanese Patent Laid-Open No. 2016-21380, the element constituting layer forming the light emitting layer is protected only by the electrode material thereon. On the other hand, in order to maintain the transparency or semi-transparency of the electrode material, the electrode material is limited to a thin metal film or transparent conductive oxide film. The moisture resistance and immersion resistance of such a thin metal film or transparent conductive oxide film are lower than those of an insulating film made of silicon nitride or the like. Therefore, in the process of patterning by photolithography, there is room for further improvement in the performance regarding the device characteristics of the light emitting element such as the luminance, driving voltage, light emission life, and the like.

### SUMMARY OF THE INVENTION

The present invention provides a technique advantageous in manufacturing a light emitting device that includes, between a first electrode layer and a second electrode layer, an element constituting layer formed by a plurality of layers including a light emitting layer.

According to one aspect of the present invention, there is provided a method of manufacturing a light emitting device, the method including forming a resist layer on the first insulating layer so as to expose a part of the first insulating layer in a region, the second electrode layer being on an element constituting layer including a light-emitting layer that is arranged on a first electrode, removing the first insulating layer, the second electrode layer, and the element constituting layer in the region, removing the resist layer after removing the first insulating layer, the second electrode layer, and the element constituting layer, forming a side wall including an insulating material, which covers side surfaces of the first insulating layer, the second electrode layer, and the element constituting layer, after removing the resist layer, and forming a contact hole in the first insulating layer on the second electrode layer after forming the side wall.

Further aspects of the present invention will become apparent from the following description of exemplary embodiments with reference to the attached drawings.

### BRIEF DESCRIPTION OF THE DRAWINGS

FIG. 1 is a sectional view schematically showing the arrangement of a light emitting device in the first embodiment.

FIGS. 2A to 2D are views each schematically showing an example of the arrangement of light emitting pixels forming the light emitting device.

FIGS. 3A to 3U are views for explaining a method of manufacturing the light emitting device in the first embodiment.

FIG. 4 is a view schematically showing from above a substrate after an etching step.

FIGS. 5A to 5H are views for explaining a modification of the method of manufacturing the light emitting device in the first embodiment.

FIGS. 6A to 6E are views for explaining a modification of the method of manufacturing the light emitting device in the first embodiment.

FIGS. 7A and 7B are views for explaining a modification of the method of manufacturing the light emitting device in the first embodiment.

FIG. 8 is a sectional view schematically showing the arrangement of a light emitting device in the second embodiment.

FIGS. 9A to 9T are views for explaining a method of manufacturing the light emitting device in the second embodiment.

FIG. 10 is a view schematically showing from above a substrate after a resist layer is peeled.

FIGS. 11A and 11B are sectional views showing an example of the arrangement of a pixel of the light emitting device in the embodiment.

FIG. 12 is a view showing an example of a display device using the light emitting device in the embodiment.

FIG. 13 is a view showing an example of a photoelectric conversion device using the light emitting device in the embodiment.

FIG. 14 is a view showing an example of an electronic apparatus using the light emitting device in the embodiment.

FIGS. 15A and 15B are views each showing an example of a display device using the light emitting device in the embodiment.

FIG. 16 is a view showing an example of an illumination device using the light emitting device in the embodiment.

FIG. 17 is a view showing an example of a moving body using the light emitting device in the embodiment.

FIGS. 18A and 18B are views each showing an example of a wearable device using the light emitting device in the embodiment.

FIGS. 19A to 19C are views showing an example of an image forming device using the light emitting device in the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

### [Light Emitting Device]

Alight emitting device in the present invention will be described. The light emitting device includes a substrate, and a first electrode layer, an element constituting layer including a light emitting layer, and a second electrode layer, which are sequentially provided on the substrate. The element constituting layer is arranged on the first electrode layer, and the second electrode layer is arranged on the element constituting layer. In this manner, the light emitting device includes, between the first electrode layer and the second electrode layer, the element constituting layer formed by a plurality of layers including the light emitting layer. Note that the second electrode layer is electrically connected to a wiring connection portion provided on the substrate.

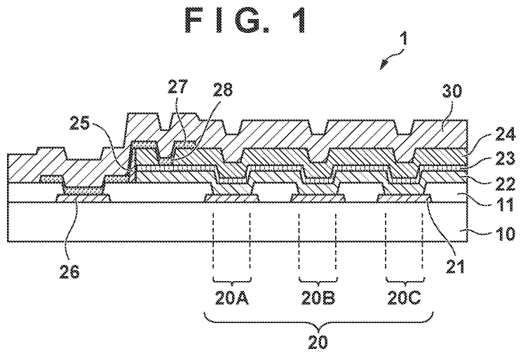

FIG. 1 is a sectional view schematically showing the arrangement of a light emitting device 1 in the first embodiment. The light emitting device 1 includes a substrate 10 including a pixel isolation film 11, and a light emitting element provided in a region corresponding to a light emitting pixel 20 on the substrate. The light emitting element includes a first electrode layer 21, an element constituting layer 22, a second electrode layer 23, and a first insulating layer 24 in this order from the substrate 10 side. The light emitting device 1 also includes a wiring connection portion 26 (electrode). The wiring connection portion 26 is an electrode member provided on the substrate 10, more specifically, in a region of the substrate 10 other than the region corresponding to the light emitting pixel 20. In this embodiment, the light emitting pixel 20 is divided into light emitting pixels 20A, 20B, and 20C.

Although not shown in FIG. 1, the substrate 10 includes an interlayer insulating layer on an underlying substrate. In this embodiment, a driving circuit and wiring for driving the light emitting element may be provided between the interlayer insulating layer and the underlying substrate. If the driving circuit and wiring are provided between the interlayer insulating layer and the underlying substrate, a contact hole is provided in a predetermined region (for example, a region where the first electrode layer 21 or the wiring connection portion 26 is provided) of the interlayer insulating layer. The contact hole is filled with a conductive member for electrically connecting the electrode member (the first electrode layer 21 or the wiring connection portion 26) provided on the interlayer insulating layer to the driving circuit and wiring.

In the light emitting device 1, openings are formed in the regions of the pixel isolation film 11 forming the substrate 10, where the first electrode layer 21 and the wiring connection portion 26 are provided. Here, the opening of the film isolation film 11 formed in the region provided with the first electrode layer 21 is a region to be the light emitting pixel 20. Therefore, the pixel isolation film 11 functions as a member (light emitting region limiting member) that limits the light emitting region. In this embodiment, examples of a method of controlling the planar shape of the light emitting pixel 20 include a method of providing the pixel isolation film 11 in a predetermined shape on the first electrode layer 21 by patterning, and a method of patterning the first electrode layer 21 in advance by photolithography or the like.

In the light emitting device 1, the first electrode layer 21 forming the light emitting element is an electrode provided on the interlayer insulating layer forming the substrate 10, and its end portion is covered with the pixel isolation film 11.

In the light emitting device 1, the element constituting layer 22 forming the light emitting element is a member selectively provided in the light emitting region and a region near the light emitting region. In this embodiment, the element constituting layer 22, the second electrode layer 23, and the first insulating layer 24 are formed by patterning using the same photomask, so that they have almost the same planar shape (planar pattern). Note that a specific patterning method will be described later together with details of the element constituting layer 22, the second electrode layer 23, and the first insulating layer 24.

In the light emitting device 1, a second insulating layer 25 is formed as a side wall that covers the side surfaces (end portions) of the patterned element constituting layer 22, second electrode layer 23, and first insulating layer 24.

In the light emitting device 1, the second electrode layer 23 provided on the element constituting layer 22 is electrically connected to the wiring connection portion 26 via a third electrode layer 27 through a contact hole 28 formed by etching the first insulating layer 24. Note that the end portion of the wiring connection portion 26 is covered with the pixel isolation film 11.

In the light emitting device 1, a sealing layer 30 is formed to cover and protect at least the element constituting layer 22. However, in the light emitting device 1, a protection member for protecting the light emitting element is not limited to the sealing layer 30. Note that, as shown in FIG. 1, the light emitting pixel 20 and the wiring connection portion 26 are provided in the sealing layer 30.

Although not shown in FIG. 1, an external connection terminal is provided outside the pixel region of the sealing layer 30. The external connection terminal is a terminal that supplies a signal from outside or a power supply voltage to a circuit (not shown). In this embodiment, the sealing layer 30 needs to be patterned so as to have an opening in a region where the external connection terminal provided on the substrate 10 is provided.

As has been described above, in the light emitting device 1, at least one light emitting element is provided on the substrate 10. If the light emitting device 1 includes two or more light emitting elements, the light emitting elements may emit light components of the same color but different colors may be extracted therefrom using color conversion layers such as color filters. Further, if the light emitting device 1 includes two or more light emitting elements, the array mode of the light emitting elements includes, for example, a mode of arraying pixels, each being formed by combining multiple light emitting elements, in a line or a matrix, but the array mode is not limited to this. In the light emitting device 1, the electrode that extracts light output from the light emitting layer forming the element constituting layer 22 may be the second electrode layer 23 or the first electrode layer 21. The mode of extracting light output from the light emitting layer is not limited to a mode of selectively extracting light from the second electrode layer 23 or the first electrode layer 21, and also includes a mode of extracting light from both the second electrode layer 23 and the first electrode layer 21. Note that when the electrode that extracts light output from the light emitting layer is a semi-transparent or transparent electrode, light can be extracted from inside the light emitting element forming the light emitting device 1.

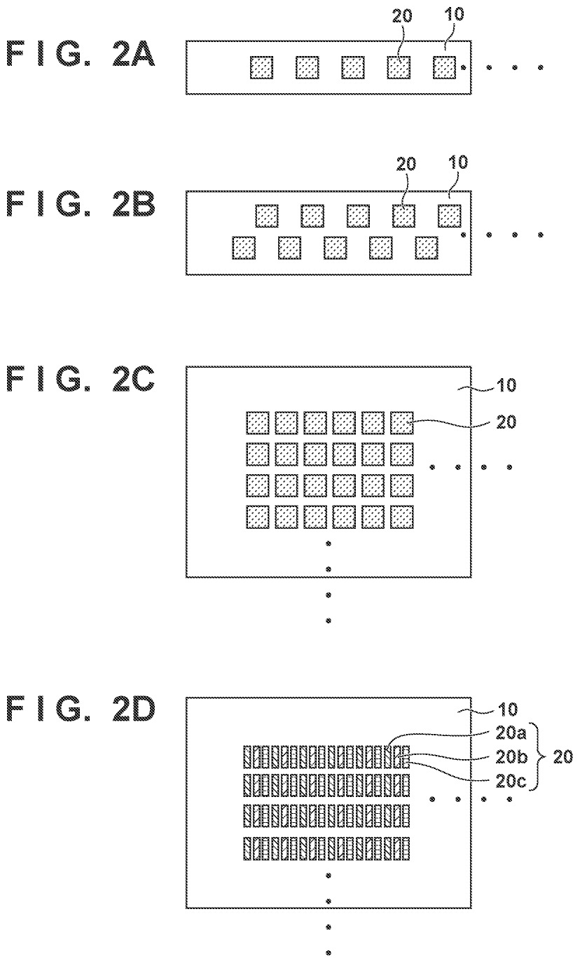

Each of FIGS. 2A to 2D is a view schematically showing an example of the arrangement of the light emitting pixels 20 forming the light emitting device 1. In this embodiment, the arrangement of the light emitting pixels 20 includes a line arrangement shown in FIG. 2A, a staggered line arrangement shown in FIG. 2B, and a two-dimensional matrix arrangement shown in each of FIGS. 2C and 2D, but is not limited thereto. When the light emitting device 1 is used as a line light source for a printhead, the line arrangement shown in FIG. 2A or the staggered line arrangement shown in FIG. 2B is applied as the arrangement of the light emitting pixels 20. When the light emitting device 1 is used as a display, the two-dimensional matrix arrangement shown in FIG. 2C or 2D is applied as the arrangement of the light emitting pixels 20. Particularly, when the light emitting pixel 20 is formed by a plurality of kinds of sub-pixels 20a, 20b, and 20c as shown in FIG. 2D, full color display is possible by appropriately employing a color conversion layer for each sub-pixel.

In this embodiment, the element constituting layer 22, the second electrode layer 23, and the first insulating layer 24 are patterned using photolithography. Therefore, as compared to patterning using a shadow mask, the patterning position can be accurately defined. In patterning using a shadow mask, due to intrusion of a deposition film caused by a gap between the substrate 10 and the shadow mask, a certain region having a smaller film thickness than the center portion of the opening is formed.

Here, in order to ensure the reliability of the light emitting element, when covering the end of the deposition film with the sealing layer 30, the end of the region having the smaller film thickness also needs to be covered with the sealing layer 30. Therefore, a large frame region must be ensured.

On the other hand, in this embodiment, as has been described above, the element constituting layer 22, the second electrode layer 23, and the first insulating layer 24 are patterned using photolithography. Accordingly, the patterning position can be accurately defined, so there is no region having the smaller film thickness due to the gap between the substrate 10 and the shadow mask. In this embodiment, the side surfaces (end portions) of predetermined layers (the element constituting layer 22, the second electrode layer 23, and the first insulating layer 24) need to be covered with the second insulating layer 25, but the frame region can be reduced as compared to patterning using the shadow mask.

As has been described above, in this embodiment, predetermined layers (the element constituting layer 22, the second electrode layer 23, and the first insulating layer 24) are patterned using photolithography. With this, in the light emitting device in which the frame region is limited in the end portions of at least the element constituting layer 22 and the second electrode layer 23, the frame region can be reduced. Further, since the frame region is reduced, the number of the light emitting devices 1 obtained from one mother glass sheet can be increased, resulting in an improvement in productivity.

In the light emitting device 1, the side surface (end portion) of at least the element constituting layer 22 is covered with the second insulating layer 25. With this, permeation of water and oxygen from the side surface of the element constituting layer 22 is suppressed. Thus, deterioration of the element constituting layer 22 due to permeation of water and oxygen from the horizontal direction (a direction parallel to the substrate surface) can be improved. By using, for the second insulating layer 25, a material having higher moisture resistance and immersion resistance than the material such as the thin metal layer or transparent conductive oxide film forming the second electrode layer 23, a higher effect of suppressing element deterioration can be obtained.

### [Method of Manufacturing Light Emitting Device]

Next, a method of manufacturing the light emitting device 1 will be described. The method of manufacturing the light emitting device 1 in this embodiment includes following manufacturing processes:
(A) a step of providing, on the first electrode layer 21, the pixel isolation film 11 functioning as a light emission limiting member which limits the light emitting region;
(B) a step of continuously forming the element constituting layer 22, the second electrode layer 23, and the first insulating layer 24 on the first electrode layer 21;
(C) a step of patterning the element constituting layer 22, the second electrode layer 23, and the first insulating layer 24 with the same planar pattern;
(D) a step of forming the second insulating layer 25 (side wall) to cover the side surfaces (end portions) of the element constituting layer 22, the second electrode layer 23, and the first insulating layer 24;
(E) a step of forming the contact hole 28 in the first insulating layer 24; and
(F) a step of electrically connecting the second electrode layer 23 and the wiring connection portion 26 via the contact hole 28.

Details of each process of the method of manufacturing the light emitting device 1 in this embodiment will be described below. In this embodiment, the step (C) of patterning the element constituting layer 22, the second electrode layer 23, and the first insulating layer 24 includes following steps:
(C1) a step of providing a resist layer on the first insulating layer 24;
(C2) a step of processing the resist layer into a mask pattern having a predetermined shape by photolithography; and
(C3) a step of removing a part of each of the element constituting layer 22, the second electrode layer 23, and the first insulating layer 24 by etching using the mask pattern.

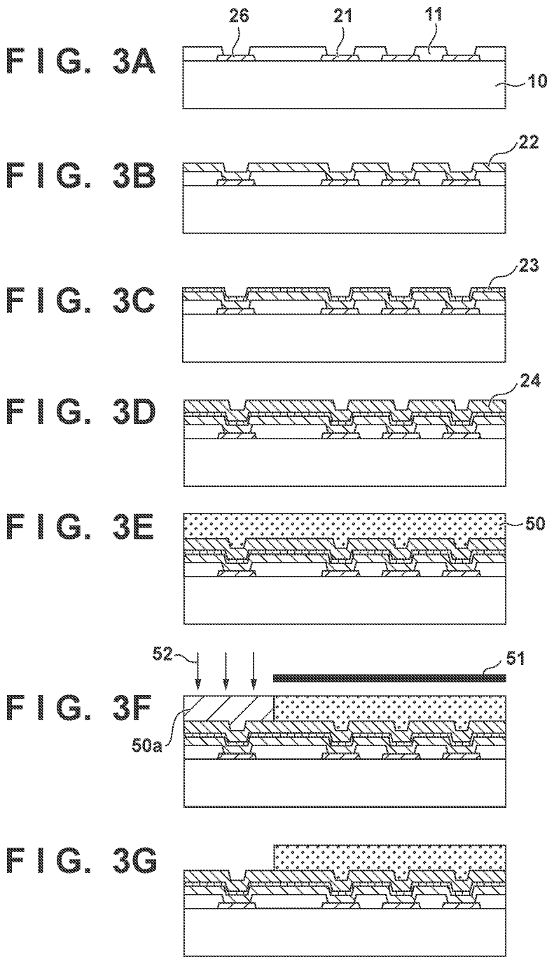

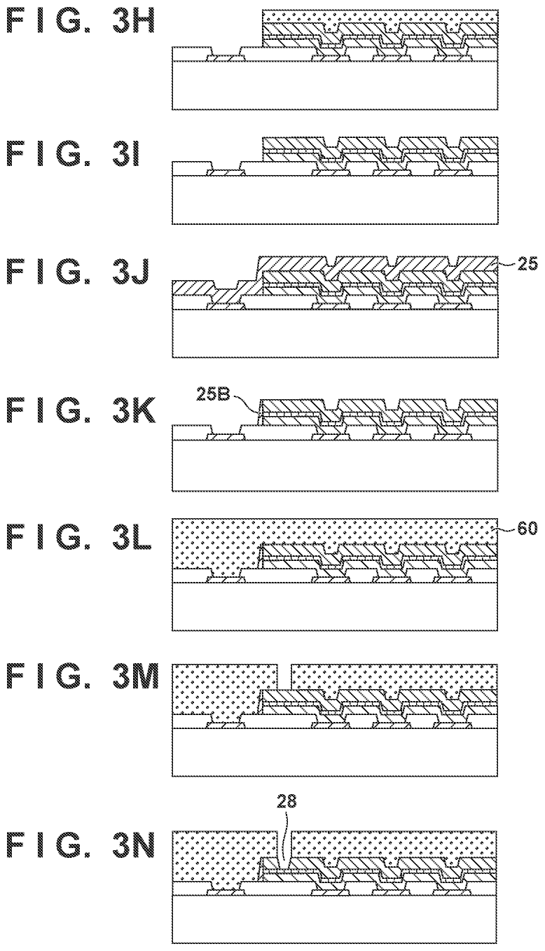

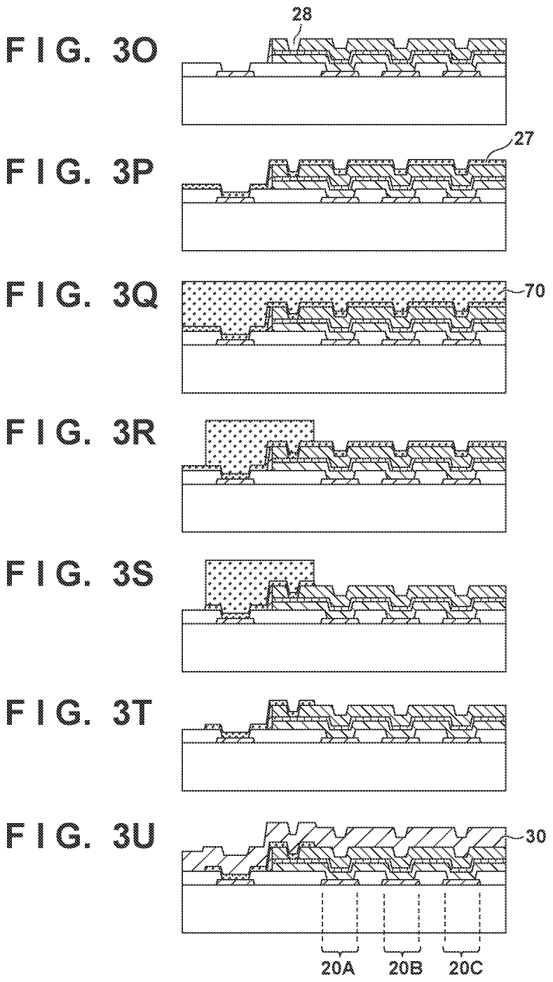

FIGS. 3A to 3U are views for explaining the method of manufacturing the light emitting device 1 in this embodiment. Each of FIGS. 3A to 3U schematically shows the section of the light emitting device 1 in each process.

### (1-1) Forming Step of Substrate

First, as shown in FIG. 3A, the substrate 10 used to manufacture the light emitting device 1 is produced. In this embodiment, the substrate 10 includes at least the pixel isolation film 11. In the substrate 10, the first electrode layer 21 is provided in a predetermined region (position), and the end portion of the first electrode layer 21 is covered with the pixel isolation film 11 functioning as the light emitting region limiting member. Openings are provided in the pixel isolation film 11 in a region corresponding to the light emitting pixel 20 and the contact position between the wiring connection portion 26 and the third electrode layer 27. Note that, although not shown in FIG. 3A, a control circuit that controls driving of the light emitting device 1 may be provided on the substrate 10. If the control circuit is provided on the substrate 10, an interlayer insulating layer and a contact hole are provided to ensure an electrical connection between the control circuit and the first electrode layer 21.

The constituent material of the first electrode layer 21 is appropriately selected in accordance with the function (whether to transmit light or reflect light) of the first electrode layer 21 with respect to light output from the light emitting layer. In a case of reflecting light output from the light emitting layer by the first electrode layer 21, the first electrode layer 21 is formed as a light reflective electrode layer. Further, in the case of reflecting light output from the light emitting layer by the first electrode layer 21, a metal material having high light reflectivity, such as aluminum (Al) or silver (Ag), is preferable as the constituent material of the first electrode layer 21. In order to reduce surface oxidation (an increase in contact resistance thereby), Ti or TiN can be used as the constituent material of the first electrode layer 21. Note that the first electrode layer 21 is not limited to be formed only by a layer made of the above-described light reflective metal material. A stacked electrode film formed by a layer made of a light reflective metal material and a layer made of a transparent conductive material such as ITO or an indium zinc oxide may be employed as the first electrode layer 21. In a case of transmitting light output from the light emitting layer by the first electrode layer 21, the first electrode layer 21 is formed as a light transmissive electrode layer. In the case of transmitting light output from the light emitting layer by the first electrode layer 21, a transparent conductive material such as ITO or an indium zinc oxide can be used as the constituent material of the first electrode layer 21.

The constituent material of the pixel isolation film 11 is not particularly limited as long as it is an insulating material, but a material containing polyimide as a main component is preferable if it is an organic material, and silicon nitride (SiN) or silicon oxide (SiO) is preferable if it is an inorganic material.

### (1-2) Step of Forming Element Constituting Layer

As shown in FIG. 3B, the element constituting layer 22 is formed on the first electrode layer 21. The element constituting layer 22 formed on the first electrode layer 21 is a stacked body formed by a single layer or a plurality of layers including at least the light emitting layer. If the element constituting layer 22 is formed by a plurality of layers, it includes, for example, a hole injection layer, a hole transport layer, an electron blocking layer, a hole blocking layer, an electron transport layer, an electron injection layer, and the like in addition to the light emitting layer. The layer arrangement of the element constituting layer 22 is not particularly limited, although it depends on the characteristics of the second electrode layer 23 to be formed in a subsequent step. The characteristics of the second electrode layer 23 mainly refer to a carrier injected from the second electrode layer 23. If the second electrode layer 23 injects holes (positive charge carrier), the layers between the first electrode layer 21 and the light emitting layer are layers that inject and transport electrons, and the layers between the second electrode layer 23 and the light emitting layer are layers that inject and transport holes. If the second electrode layer 23 injects electrons (negative charge carrier), the layers between the first electrode layer 21 and the light emitting layer are layers that inject and transport holes, and the layers between the second electrode layer 23 and the light emitting layer are layers that inject and transport electrons.

Preprocessing is preferably performed before forming the element constituting layer 22. For example, the substrate 10 is subjected to an argon plasma treatment, an oxygen plasma treatment, a UV irradiation treatment, annealing, and the like to improve the charge injection property of the first electrode layer 21 and to remove contaminants generated on the first electrode layer 21.

Examples of a method of forming the element constituting layer 22 include a coating method such as spin coating, slit coating, or ink jetting, a deposition method by a vacuum deposition method, and the like. From the viewpoint of element performance, the element constituting layer 22 is often formed by the vacuum deposition method, but this embodiment does not limit the method of forming the element constituting layer 22.

The respective layers forming the element constituting layer 22 will be described. The hole injection layer is provided between the hole transport layer and a hole injection electrode (anode). Improving the hole injection performance contributes to the lower voltage and longer life of the light emitting element forming the light emitting device 1. In this embodiment, the hole injection layer is a layer containing an organic compound having an electron-withdrawing substituent. Further, in this embodiment, at least one layer of the layers forming the element constituting layer 22 preferably functions as a layer that covers the end portion of the hole injection layer to protect the hole injection layer.

The hole transport layer is a layer mainly made of a material having a function of transporting holes.

The electron blocking layer is a layer provided between the light emitting layer and the hole transport layer, and having a function of blocking electrons leaking from the light emitting layer to the anode side, thereby confining electrons in the light emitting layer. The electron blocking layer promotes the high efficiency of the light emitting element forming the light emitting device 1.

The light emitting layer is a layer mainly for causing light emission by recombining holes and electrons. From the viewpoint of the element characteristics, the light emitting layer is preferably made of a plurality of materials.

The hole blocking layer is provided between the electron transport layer and the light emitting layer. The hole blocking layer is a layer having a function of blocking holes leaking from the light emitting layer to the cathode side, thereby confining holes in the light emitting layer. The hole blocking layer promotes the high efficiency of the light emitting element forming the light emitting device 1.

The electron transport layer is mainly for transporting electrons.

The electron injection layer is provided between the electron transport layer and an electron injection electrode (cathode). The electron injection layer is a layer which mainly contributes to the lower voltage and longer life of the light emitting element forming the light emitting device 1 by improving the electron injection performance.

Even if any of the layers is omitted or overlapped in the above-described stacked layer structure (stacked body), this does not influence the arrangement of the side surface (end portion) of the element constituting layer 22. Hence, the effect of the present invention is not influenced by the stacked layer structure of the element constituting layer 22. The stacking order of the layers forming the element constituting layer 22 is decided depending on whether the first electrode layer 21 is the anode or the cathode, but the stacking order of the layers is not limited in this embodiment.

### (1-3) Step of Forming Second Electrode Layer

As shown in FIG. 3C, the second electrode layer 23 is formed on the element constituting layer 22. As shown in FIG. 3C, the second electrode layer 23 is formed over the entire surface of the substrate 10.

The constituent material of the second electrode layer 23 is appropriately selected in accordance with the function (whether to transmit light or reflect light) of the second electrode layer 23 with respect to light output from the light emitting layer. In a case of reflecting light output from the light emitting layer by the second electrode layer 23, the second electrode layer 23 is formed as a light reflective electrode layer. In addition, in the case of reflecting light output from the light emitting layer by the second electrode layer 23, a metal material having high light reflectivity, such as aluminum (Al) or silver (Ag), is preferable as the constituent material of the second electrode layer 23. Note that the second electrode layer 23 is not limited to be formed only by a layer made of the above-described light reflective metal material. A stacked electrode film formed by a layer made of a light reflective metal material and a layer made of a transparent conductive material such as ITO or an indium zinc oxide may be employed as the second electrode layer 23. In a case of transmitting light output from the light emitting layer by the second electrode layer 23, the second electrode layer 23 is formed as a light transmissive electrode layer. In the case of transmitting light output from the light emitting layer by the second electrode layer 23, a transparent conductive material such as ITO or an indium zinc oxide can be used as the constituent material of the second electrode layer 23. Alternatively, the second electrode layer 23 may have a stacked structure in which a transparent conductive oxide material is formed on a layer made of a semi-transparent light reflective metal material. If the second electrode layer 23 employs the stacked structure, for example, as will be described layer, when forming the contact hole 28 by etching the first insulating layer 24 from above the second electrode layer 23, disappearance (risk) due to overetching can be reduced.

### (1-4) Step of Forming First Insulating Layer

As shown in FIG. 3D, the first insulating layer 24 is formed on the second electrode layer 23. As shown in FIG. 3D, the first insulating layer 24 is formed over the entire surface of the substrate 10.

As the constituent material of the first insulating layer 24, an insulating material having low gas permeability to water and oxygen, such as silicon nitride (SiN) or silicon oxide (SiO), can be used, but the constituent material is not limited to these materials. As a method of forming the first insulating layer 24, a Chemical Vapor Deposition method (CVD) or an Atom Layer Deposition method (ALD) can be used, but the method is not limited to these methods. The first insulating layer 24 may be not a signal layer but a stacked layer structure formed by a plurality of different materials, and the film thickness may be different between the layers. The layers of the first insulating layer 24 may be formed by methods different from each other, and a combination thereof is not limited.

### (1-5) Exposure Step

After forming the element constituting layer 22, the second electrode layer 23, and the first insulating layer 24 on the entire surface of the substrate 10 including the first electrode layer 21, a resist layer 50 is formed over the entire surface of the substrate 10 as shown in FIG. 3E. The resist layer 50 is formed by, for example, a wet deposition method such as a coating method. This embodiment employs a photolithography process using a positive photoresist, but a photolithography process using a negative photoresist may be employed.

Next, the resist layer 50 formed on a region other than the region where the patterned element constituting layer 22, second electrode layer 23, and first insulating layer 24 are to be provided is selectively removed. For example, if the resist layer 50 is a positive resist, as shown in FIG. 3F, the resist layer 50 is exposed by irradiating it with exposure light 52 via a mask 51 including an opening in a region other than a region where the element constituting layer 22 is to be provided. With this, a resist layer 50a exposed so as to surround at least the light emitting pixel 20 is formed. On the other hand, if the resist layer 50 is a negative resist, the resist layer 50 is exposed by irradiating it with exposure light via a mask including an opening in a region where the element constituting layer 22 is to be provided. With this, the exposed resist layer 50a in the same shape as described above can be formed.

### (1-6) Patterning Step

Next, as shown in FIG. 3G, the exposed resist layer 50a is removed by developing it with a developer, and dry etching is performed using the patterned resist layer 50 as a mask. A specific method of dry etching is not particularly limited as long as it is possible to etch the element constituting layer 22, the second electrode layer 23, and the first insulating layer 24 and a gas is used, which does not permeate the light emitting element from the end faces of these layers and deteriorate the element characteristics. The gas used for dry etching is not limited to one kind. Different gases may be used for the respective layers, or a plurality of gases may be used for one layer.

### (1-7) Resist Peeling Step

FIG. 3H shows a state in which the resist layer 50 remains on the first insulating layer 24 after dry etching of the element constituting layer 22, the second electrode layer 23, and the first insulating layer 24 is completed. As shown in FIG. 3I, the remaining resist layer 50 can be removed using a peeling solution or the like. However, if there is a possibility that the peeling solution permeates from the side surface (end portion) of the element constituting layer 22 and dissolves the element constituting layer 22 or affects the characteristics of the light emitting element, the resist layer 50 is preferably removed by a dry process such as ashing.

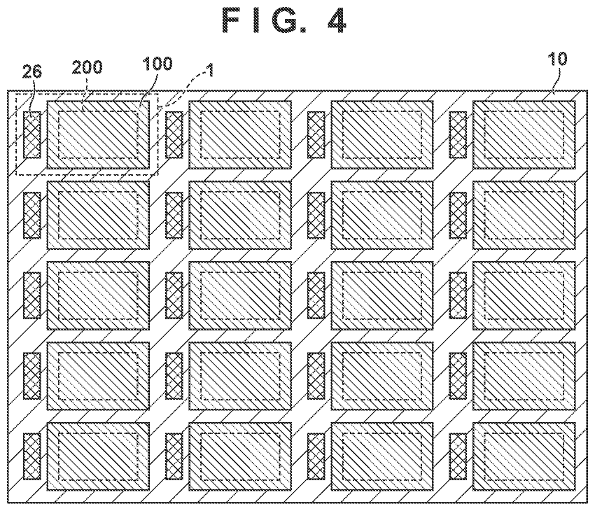

FIG. 4 is a view schematically showing from above the substrate 10 after the etching step. At least one or more light emitting devices 1 are arranged on the substrate 10. The light emitting device 1 includes at least a stacked region 100, a light emitting region 200, and the wiring connection portion 26. The stacked region 100 is formed by the element constituting layer 22, the second electrode layer 23, and the first insulating layer 24, and its end face exists outside the light emitting region 200 including the light emitting pixel 20. The wiring connection portion 26 is formed outside the stacked region 100. In FIG. 4, the wiring connection portion 26 has a rectangular shape, but the shape of the wiring connection portion 26 is not particularly limited. The wiring connection portion 26 may be formed so as to surround the stacked region 100.

### (1-8) Step of Forming Second Insulating Layer

Next, as shown in FIG. 3J, the second insulating layer 25 is formed on the substrate 10. As shown in FIG. 3J, the second insulating layer 25 is formed over the entire surface of the substrate 10.

As the constituent material of the second insulating layer 25, an insulating material having low gas permeability to water and oxygen, such as silicon nitride (SiN) or silicon oxide (SiO), can be used, but the constituent material is not limited to these materials. As a method of forming the second insulating layer 25, a Chemical Vapor Deposition method (CVD) or an Atom Layer Deposition method (ALD) can be used, but the method is not limited to these methods. The second insulating layer 25 may be not a signal layer but a stacked body (stacked layer structure) formed by a plurality of different materials, and the film thickness may be different between the layers. The layers of the second insulating layer 25 may be formed by methods different from each other, and a combination thereof is not limited.

### (1-9) Etch Back Step of Second Insulating Layer

After the second insulating layer 25 is formed, etch back is performed. By etching back the second insulating layer 25 under an appropriate condition, as shown in FIG. 3K, the second insulating layer 25 can be left on the side surfaces of the element constituting layer 22, the second electrode layer 23, and the first insulating layer 24. In other words, the second insulating layer 25 is removed except the portion on the side surfaces of the element constituting layer 22, the second electrode layer 23, and the first insulating layer 24 is removed. In this manner, the second insulating layer 25 having moisture resistance and gas permeation resistance is used as the side wall covering the side surface (end portion) of the element constituting layer 22. With this, during a wet process such as photolithography in a subsequent step, which is performed under air atmosphere, it is possible to suppress permeation of oxygen and water (liquid) into the element constituting layer 22. Accordingly, it is possible to manufacture the light emitting device 1 with suppressed deterioration of the light emitting element.

### (1-10) Step of Patterning First Insulating Layer

Next, patterning of the first insulating layer 24 is performed. As shown in FIG. 3L, a resist layer 60 is formed on the entire surface of the substrate 10, and exposure and development are performed. With this, as shown in FIG. 3M, the resist layer 60 on the first insulating layer 24 in a region other than the light emitting region (pixel region) is removed. Then, as shown in FIG. 3N, the first insulating layer 24 in the region where the resist layer 60 has been removed is etched until the second electrode layer 23 is exposed, thereby forming the contact hole 28. At this time, unless the etching gas or etching solution permeates the second electrode layer 23 and causes deterioration of the characteristics of the light emitting element, etching of the first insulating layer 24 may be dry etching or wet etching. The shape of the contact hole 28 is not particularly limited to a circular shape, but may be a dot or linear shape. The contact hole 28 may be formed by a plurality of openings, or may be formed by a combination of openings having different shapes.

After the contact hole 28 is formed, as shown in FIG. 3O, the resist layer 60 is peeled. The resist layer 60 may be peeled by a wet process using a solution, by a dry process using ashing, or by a combination thereof. Even if the wet process is used, since the second insulating layer 25 covers the side surface of the element constituting layer 22 including the light emitting layer, permeation of a peeling solution into the element constituting layer 22 can be prevented, so that deterioration of the characteristics of the light emitting element can be suppressed.

### (1-11) Step of Forming Third Electrode Layer

Next, as shown in FIG. 3P, the third electrode layer 27 is formed over the entire surface of the patterned substrate 10. The third electrode layer 27 electrically connects the second electrode layer 23 and the wiring connection portion 26. As the material of the third electrode layer 27, a low resistance material such as Ag or Al is preferable, but the material is not particularly limited as long as it is a conductive material. Note that, since the third electrode layer 27 is patterned in a subsequent step, there is no problem in using a metal film that hardly transmits light as long as it does not exist in a light extraction path.

### (1-12) Step of Patterning Third Electrode Layer

Next, patterning of the third electrode layer 27 is performed. As shown in FIG. 3Q, a resist layer 70 is formed over the entire surface of the substrate 10, and exposure and development are performed to remove the resist layer 70 existing on the light emitting pixel 20 as shown in FIG. 3R. Further, the third electrode layer 27 is etched, thereby removing the third electrode layer 27 in the region where the resist layer 70 does not exist, as shown in FIG. 3S. Unless the etching gas or etching solution permeates the first insulating layer 24, etching of the third electrode layer 27 may be dry etching or wet etching. At this time, the first insulating layer 24 protects the element constituting layer 22 and the second electrode layer 23 from the etching gas or the etching solution. Then, as shown in FIG. 3T, the resist layer 70 on the third electrode layer 27 is removed.

### (1-13) Sealing Step

After patterning the third electrode layer 27, the light emitting element and wiring connection portion 26 forming the light emitting device 1 are sealed by a glass cap or a sealing thin film made of an inorganic material. In this embodiment, as shown in FIG. 3U, the sealing layer 30 as a sealing thin film made of an inorganic material is formed on the third electrode layer 27 and the first insulating layer 24. As the constituent material of the sealing layer 30, an inorganic material having high moisture resistance, for example, silicon nitride, silicon oxide (SiO), aluminum oxide (AlO), or the like can be used. Note that the material itself and composition ratio of the sealing layer 30 are not particularly limited as long as sealing by the thin film is possible. As a method of forming the sealing layer 30, a Chemical Vapor Deposition method (CVD) or an Atom Layer Deposition method (ALD) can be used, but the method is not limited to these methods.

In this embodiment, after the sealing layer 30 is formed, patterning of the sealing layer 30 may be performed to expose an electrode pad (external connection terminal) for external connection used for a connection with an external circuit. The end portions of the element constituting layer 22, the second electrode layer 23, and the first insulating layer 24 are preferably covered with the sealing layer 30. With this, it is possible to further prevent permeation of water and oxygen from the end portion of the element constituting layer 22, so that the durability of the element forming the light emitting device 1 can be further improved.

### (Modification 1)

Consider a case in which the contact hole 28 is formed by etching the first insulating layer 24 as shown in FIG. 3N. If the second electrode layer 23 is thin, during overetching of the first insulating layer 24, the second electrode layer 23 and the element constituting layer 22 (pattern thereof) are also removed by etching. In this case, the second electrode layer 23 and the third electrode layer 27 cannot be electrically connected, and the process margin of the etching condition decreases. To prevent this, the second electrode layer 23 is formed as a stacked body formed by a plurality of layers and, for example, a transparent conductive film is used for one of the plurality of layers. With this, it is possible to avoid that the second electrode layer 23 is removed (disappears) during the overetching.

### (Modification 2)

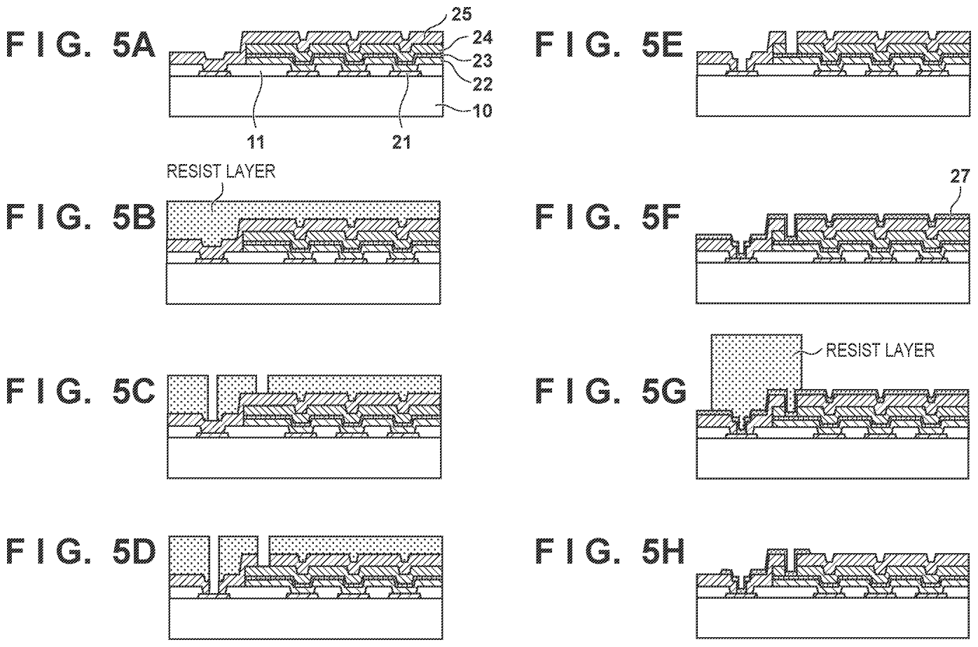

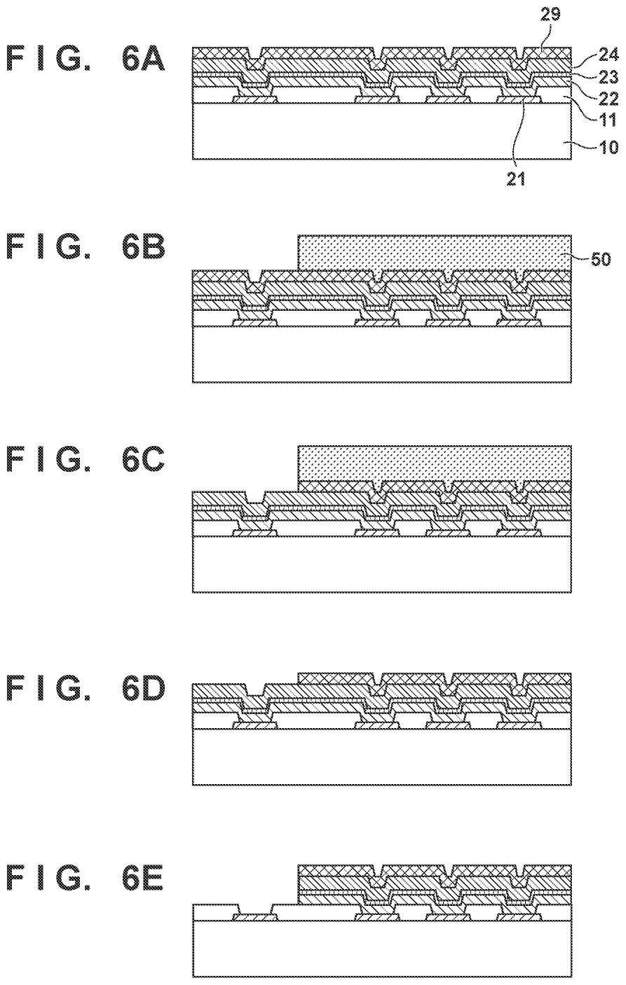

With reference to FIGS. 5A to 5H, a modification of the method of manufacturing the light emitting device 1 in this embodiment will be described. As shown in FIG. 5A, after the second insulating layer 25 is formed, patterning of the second insulating layer 25 is performed by photolithography as shown in FIGS. 5B to 5E without performing etching back. With this, it is possible to more thickly cover the side surfaces of the element constituting layer 22, the second electrode layer 23, and the first insulating layer 24 with the second insulating layer 25 (increase the thickness of the wide wall). Accordingly, it is possible to form the light emitting element having high resistance against a gas and water (liquid). Note that steps shown in FIGS. 5F, 5G, and 5H are similar to steps shown in FIGS. 3P, 3R, and 3T, respectively, so that a description thereof will be omitted here.

### (Modification 3)

With reference to FIGS. 6A to 6E, a modification of the method of manufacturing the light emitting device 1 in this embodiment will be described. When patterning the element constituting layer 22, the second electrode layer 23, and the first insulating layer 24, a hard mask layer 29 may be formed on the first insulating layer 24 as shown in FIG. 6A. The material of the hard mask layer 29 is preferably a material which is different from the material of the first insulating layer 24 and ensures high selectivity in etching with the material of the first insulating layer 24. As shown in FIGS. 6B and 6C, patterning is performed using photolithography so as to remove the hard mask layer 29 and leave the first insulating layer 24. Then, as shown in FIG. 6D, the resist layer 50 on the hard mask layer 29 is peeled. Here, even if a peeling solution is used to peel the resist layer 50, since the first insulating layer 24 prevents permeation of the peeling solution, deterioration of the characteristics of the light emitting element can be suppressed. In this manner, by dry-etching the element constituting layer 22, the second electrode layer 23, and the first insulating layer 24 while using, as a mask, the hard mask layer 29 patterned as described above, patterning of these layers can be performed as shown in FIG. 6E.

Note that when peeling the resist layer 50, the resist layer 50 can be reliably peeled (removed) by a combination of the peeling solution and ashing. However, even if the peeling solution is used, since the hard mask layer 29 is provided, an influence on the characteristics of the light emitting element can be suppressed.

After patterning the element constituting layer 22, the second electrode layer 23, and the first insulating layer 24, the hard mask layer 29 may be left as intact or removed. If the hard mask layer 29 is removed, the hard mask layer 29 may be removed by etching back, or may be removed after the second insulating layer 25 is formed. However, in the etching process for removing the hard mask layer 29, an etching gas or an etching solution may permeate from the end faces of the element constituting layer 22, the second electrode layer 23, and the first insulating layer 24. In this case, the hard mask layer 29 is removed after the second insulating layer 25 is formed.

### (Modification 4)

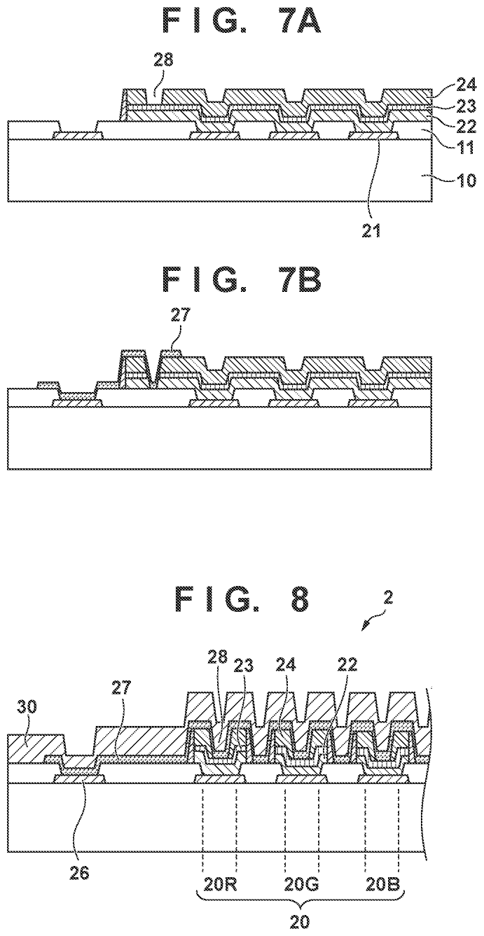

An electric connection between the third electrode layer 27 and the second electrode layer 23 can also be implemented via the side surface of the second electrode layer 23. When forming the contact hole 28 for connecting the third electrode layer 27 and the second electrode layer 23, as shown in FIG. 7A, the underlying second electrode layer 23 and element constituting layer 22 are also etched by overetching the first insulating layer 24. Then, as shown in FIG. 7B, the third electrode layer 27 is formed such that the side surface (the surface on the contact hole 28 side) of the second electrode layer 23 and the third electrode layer 27 are electrically connected.

If the second electrode layer 23 is thin, when forming the contact hole 28, it is required to decrease the process margin of the etching condition to leave the second electrode layer 23 over the entire surface of the substrate 10. However, by forming the third electrode layer 27 such that the third electrode layer 27 is electrically connected to the side surface of at least the second electrode layer 23, the process margin of the etching condition can be increased.

### Second Embodiment

### [Light Emitting Device]

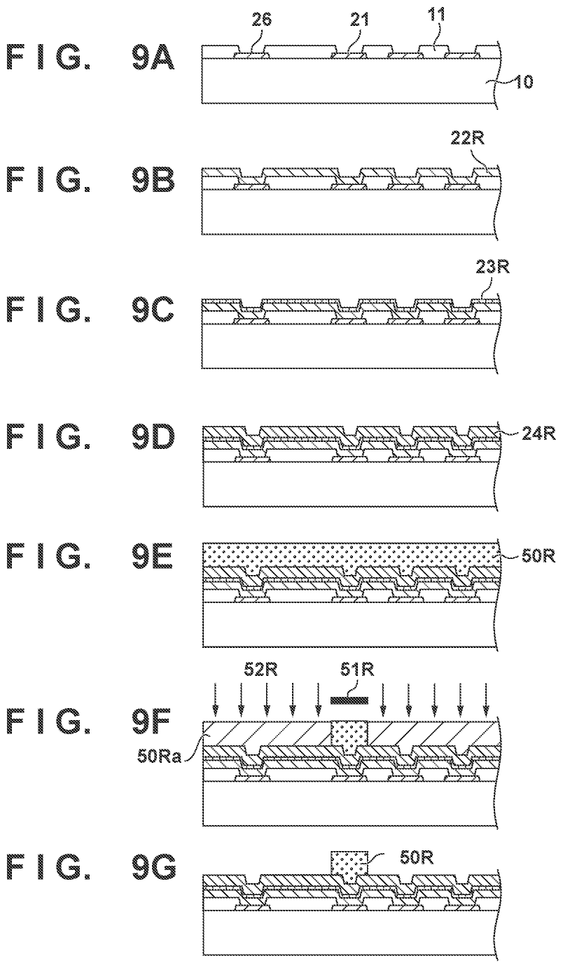

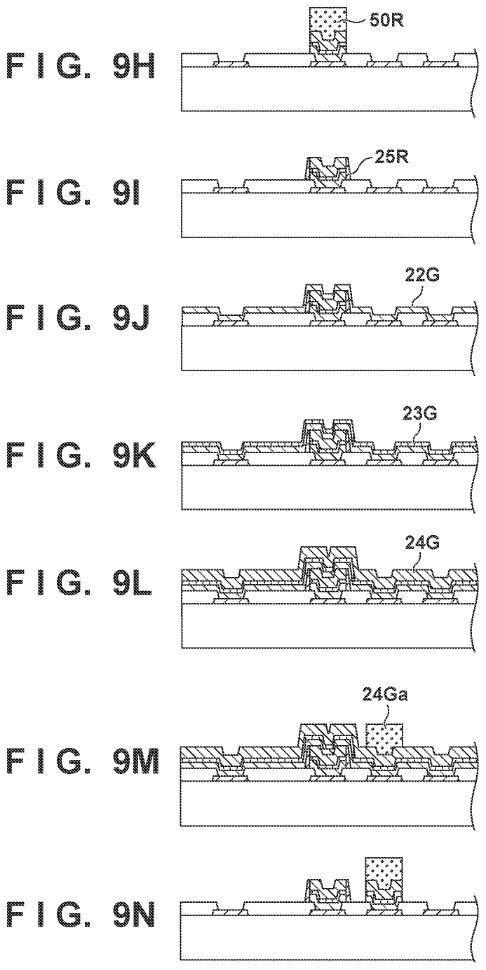

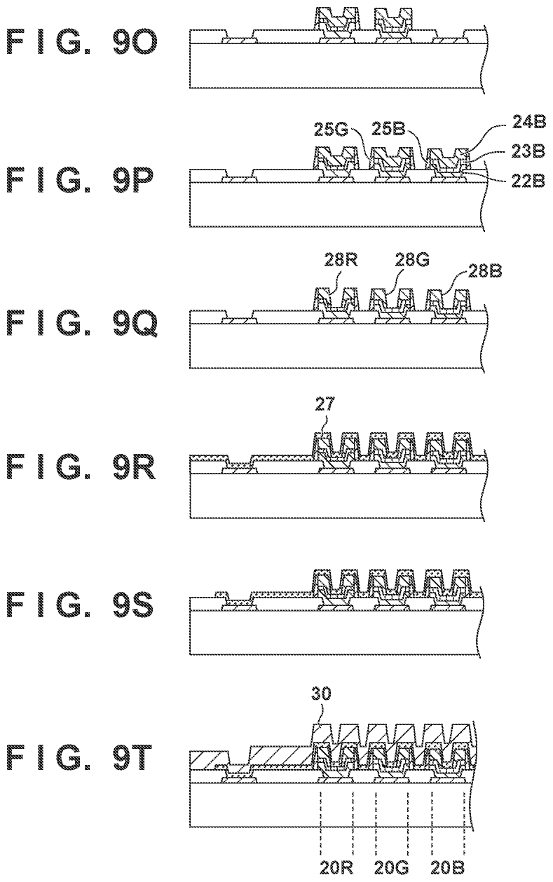

FIG. 8 is a sectional view schematically showing the arrangement of a light emitting device 2 in the second embodiment. The light emitting device 2 includes a substrate 10 including a pixel isolation film 11, and a light emitting element provided in a region corresponding to a light emitting pixel 20 on the substrate. The light emitting element includes a first electrode layer 21, an element constituting layer 22, a second electrode layer 23, and a first insulating layer 24 in this order from the substrate 10 side. The light emitting device 2 also includes a wiring connection portion 26 (electrode). The wiring connection portion 26 is an electrode member provided on the substrate 10, more specifically, in a region of the substrate 10 other than the region corresponding to the light emitting pixel 20.

Although not shown in FIG. 8, the substrate 10 includes an interlayer insulating layer on an underlying substrate. In this embodiment, a driving circuit and wiring for driving the light emitting element may be provided between the interlayer insulating layer and the underlying substrate. If the driving circuit and wiring are provided between the interlayer insulating layer and the underlying substrate, a contact hole is provided in a predetermined region (for example, a region where the first electrode layer 21 or the wiring connection portion 26 is provided) of the interlayer insulating layer. The contact hole is filled with a conductive member for electrically connecting the electrode member (the first electrode layer 21 or the wiring connection portion 26) provided on the interlayer insulating layer to the driving circuit and wiring.

In the light emitting device 2, openings are formed in the regions of the pixel isolation film 11 forming the substrate 10, where the first electrode layer 21 and the wiring connection portion 26 are provided. Here, the opening of the film isolation film 11 formed in the region provided with the first electrode layer 21 is a region to be the light emitting pixel 20. Therefore, the pixel isolation film 11 functions as a member (light emitting region limiting member) that limits the light emitting region. In this embodiment, examples of a method of controlling the planar shape of the light emitting pixel 20 include a method of providing the pixel isolation film 11 in a predetermined shape on the first electrode layer 21 by patterning, and a method of patterning the first electrode layer 21 in advance by photolithography or the like.

In the light emitting device 2, the first electrode layer 21 forming the light emitting element is an electrode provided on the interlayer insulating layer forming the substrate 10, and its end portion is covered with the pixel isolation film 11.

In the light emitting device 2, the element constituting layer 22 forming the light emitting element is a member selectively provided in the light emitting region and a region near the light emitting region. In this embodiment, the element constituting layer 22, the second electrode layer 23, and the first insulating layer 24 are formed by patterning using the same photomask, so that they have almost the same planar shape (planar pattern).

In the light emitting device 2, a second insulating layer 25 is formed as a side wall that covers the side surfaces (end portions) of the patterned element constituting layer 22, second electrode layer 23, and first insulating layer 24.

In the light emitting device 2, the second electrode layer 23 provided on the element constituting layer 22 is electrically connected to the wiring connection portion 26 via a third electrode layer 27 through a contact hole 28 formed by etching the first insulating layer 24. Note that the end portion of the wiring connection portion 26 is covered with the pixel isolation film 11.

In the light emitting device 2, a sealing layer 30 is formed to cover and protect at least the element constituting layer 22. However, in the light emitting device 2, a protection member for protecting the light emitting element is not limited to the sealing layer 30. Note that, as shown in FIG. 8, the light emitting pixel 20 and the wiring connection portion 26 are provided under the sealing layer 30.

Although not shown in FIG. 8, an external connection terminal is provided outside the pixel region of the sealing layer 30. The external connection terminal is a terminal that supplies a signal from outside or a power supply voltage to a circuit (not shown). In this embodiment, the sealing layer 30 needs to be patterned so as to have an opening in a region where the external connection terminal provided on the substrate 10 is provided.

As has been described above, in the light emitting device 2, at least one light emitting element is provided on the substrate 10. If the light emitting device 2 includes two or more light emitting elements, the light emitting elements may emit light components of the same color or different colors. Further, if the light emitting device 2 includes two or more light emitting elements, the array mode of the light emitting elements includes, for example, a mode of arraying pixels, each being formed by combining multiple light emitting elements, in a line or a matrix, but the array mode is not limited to this. In the light emitting device 2, the electrode that extracts light output from the light emitting layer forming the element constituting layer 22 may be the second electrode layer 23 or the first electrode layer 21. The mode of extracting light output from the light emitting layer is not limited to a mode of selectively extracting light from the second electrode layer 23 or the first electrode layer 21, and also includes a mode of extracting light from both the second electrode layer 23 and the first electrode layer 21. Note that when the electrode that extracts light output from the light emitting layer is a semi-transparent or transparent electrode, light can be extracted from inside the light emitting element forming the light emitting device 2.

In this embodiment, the arrangement of the light emitting pixels 20 includes a line arrangement shown in FIG. 2A, a staggered line arrangement shown in FIG. 2B, and a two-dimensional matrix arrangement shown in each of FIGS. 2C and 2D, but not limited thereto. When the light emitting device 2 is used as a line light source for a printhead, the line arrangement shown in FIG. 2A or the staggered line arrangement shown in FIG. 2B is applied as the arrangement of the light emitting pixels 20. When the light emitting device 2 is used as a display, the two-dimensional matrix arrangement shown in FIG. 2C or 2D is applied as the arrangement of the light emitting pixels 20. Particularly, when the light emitting pixel 20 is formed by a plurality of sub-pixels 20a, 20b, and 20c as shown in FIG. 2D, full color display is possible by appropriately employing a color conversion layer for each sub-pixel.

In this embodiment, the element constituting layer 22, the second electrode layer 23, and the first insulating layer 24 are patterned using photolithography. Therefore, as compared to patterning using a shadow mask, the patterning position can be accurately defined. In patterning using a shadow mask, due to intrusion of a deposition film caused by a gap between the substrate 10 and the shadow mask, a certain region having a smaller film thickness than the center portion of the opening is formed.

Here, in order to ensure the reliability of the light emitting element, when covering the end of the deposition film with the sealing layer 30, the end of the region having the smaller film thickness also needs to be covered with the sealing layer 30. Therefore, a large frame region must be ensured.

On the other hand, in this embodiment, as has been described above, the element constituting layer 22, the second electrode layer 23, and the first insulating layer 24 are patterned using photolithography. Accordingly, the patterning position can be accurately defined, so there is no region having the smaller film thickness due to the gap between the substrate 10 and the shadow mask. In this embodiment, the side surfaces (end portions) of predetermined layers (the element constituting layer 22, the second electrode layer 23, and the first insulating layer 24) need to be covered with the second insulating layer 25, but the pixel accuracy can be increased as compared to patterning using the shadow mask.

As has been described above, in this embodiment, predetermined layers (the element constituting layer 22, the second electrode layer 23, and the first insulating layer 24) are patterned using photolithography. With this, in the light emitting device in which the sub-pixel region is limited in the end portions of at least the element constituting layer 22 and the second electrode layer 23, the pixel accuracy can be increased. In addition, in the light emitting device in which a frame region is limited in the end portions of the element constituting layer 22 and the second electrode layer 23, the frame region can be reduced.

In the light emitting device 2, the side surface (end portion) of at least the element constituting layer 22 is covered with the second insulating layer 25. With this, permeation of water and oxygen from the side surface of the element constituting layer 22 is suppressed. Thus, deterioration of the element constituting layer 22 due to permeation of water and oxygen from the horizontal direction (a direction parallel to the substrate surface) can be improved. By using, for the second insulating layer 25, a material having higher moisture resistance and immersion resistance than the material such as the thin metal layer or transparent conductive oxide film forming the second electrode layer 23, a higher effect of suppressing element deterioration can be obtained.

### [Method of Manufacturing Light Emitting Device]

Next, a method of manufacturing the light emitting device 2 will be described. The method of manufacturing the light emitting device 2 in this embodiment includes following manufacturing processes:
(A) a step of providing, on the first electrode layer 21, the pixel isolation film 11 functioning as a light emission limiting member which limits the light emitting region;
(B) a step of continuously forming the element constituting layer 22, the second electrode layer 23, and the first insulating layer 24 on the first electrode layer 21;
(C) a step of patterning the element constituting layer 22, the second electrode layer 23, and the first insulating layer 24 with the same planar pattern;
(D) a step of forming the second insulating layer 25 (side wall) to cover the side surfaces (end portions) of the element constituting layer 22, the second electrode layer 23, and the first insulating layer 24;
(E) a step of forming sub-pixels of different light emission colors by repeating steps (B), (C), and (D) while changing the combination of materials of the element constituting layer 22;
(F) a step of forming the contact hole 28 in the first insulating layer 24 on the pixel; and
(G) a step of electrically connecting the second electrode layer 23 and the wiring connection portion 26 via the contact hole 28.

Details of each process of the method of manufacturing the light emitting device 2 in this embodiment will be described below. In this embodiment, the step (C) of patterning the element constituting layer 22, the second electrode layer 23, and the first insulating layer 24 includes following steps:
(C1) a step of providing a resist layer on the first insulating layer 24;
(C2) a step of processing the resist layer into a mask pattern having a predetermined shape by photolithography; and
(C3) a step of removing a part of each of the element constituting layer 22, the second electrode layer 23, and the first insulating layer 24 by etching using the mask pattern.

FIGS. 9A to 9T are views for explaining the method of manufacturing the light emitting device 2 in this embodiment. Each of FIGS. 9A to 9T schematically shows the section of the light emitting device 2 in each process.

In this embodiment, the method of manufacturing the light emitting device 2 (display) with full color display will be described, in which each sub-pixel includes one of an R light emitting layer (sub-pixel 20R), a G light emitting layer (sub-pixel 20G), and a B light emitting layer (sub-pixel 20B), that is, pixels of at least two different colors are included. Note that the order of manufacturing the sub-pixels and the colors of the light emitting layers are not limited to those described above.

Since the process from the step of forming the substrate 10 to the step of forming the first insulating layer 24 shown in FIGS. 9A to 9D is similar to that in the first embodiment, a description thereof will be omitted here.

### (2-1) Exposure Step

After forming an element constituting layer 22R, a second electrode layer 23R, and a first insulating layer 24R on the entire surface of the substrate 10 including a first electrode layer 21R, a resist layer 50R is formed over the entire surface of the substrate 10 as shown in FIG. 9E. The resist layer 50R is formed by, for example, a wet deposition method such as a coating method. This embodiment employs a photolithography process using a positive photoresist, but a photolithography process using a negative photoresist may be employed.

Next, the resist layer 50R existing outside the element constituting layer 22R, second electrode layer 23R, and first insulating layer 24R of the sub-pixel 20R is selectively removed. For example, if the resist layer 50R is a positive resist, as shown in FIG. 9F, the resist layer 50R is exposed by irradiating it with exposure light 52R via a mask 51R including an opening in a region other than a region where the element constituting layer 22R is to be provided. With this, a resist layer 50Ra exposed so as to surround at least the light emitting pixel 20R is formed. On the other hand, if the resist layer 50R is a negative resist, the resist layer 50R is exposed by irradiating it with exposure light via a mask including an opening in a region where the element constituting layer 22R is to be provided. With this, the exposed resist layer 50Ra in the same shape as described above can be formed. On the other hand, if the resist layer 50R is formed by the negative resist, it is possible to form the exposed resist layer 50Ra in the same shape as described above by using a mask with the reversed opening pattern.

### (2-2) Patterning Step

Next, as shown in FIG. 9G, the exposed resist layer 50Ra is removed by developing it with a developer, and dry etching is performed using the patterned resist layer 50R as a mask. A specific method of dry etching is not particularly limited as long as it is possible to etch the element constituting layer 22R, the second electrode layer 23R, and the first insulating layer 24R and a gas is used, which does not permeate the light emitting element from the end faces of these layers and deteriorate the element characteristics. The gas used for dry etching is not limited to one kind. Different gases may be used for the respective layers, or a plurality of gases may be used for one layer.

FIG. 9H shows a state in which the resist layer 50R remains on the first insulating layer 24R after dry etching of the element constituting layer 22R, the second electrode layer 23R, and the first insulating layer 24R is completed. The remaining resist layer 50R can be removed using a peeling solution or the like. However, if there is a possibility that the peeling solution permeates from the side surface (end portion) of the element constituting layer 22R and affects the characteristics of the light emitting element, the resist layer 50R is preferably removed by a dry process such as ashing.

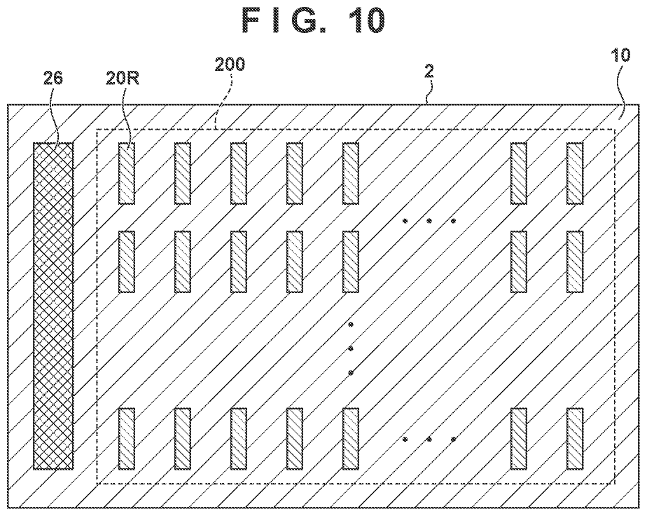

FIG. 10 is a view schematically showing from above the substrate 10 after the resist layer 50R is peeled. The sub-pixel 20R is formed by stacking the element constituting layer 22R, the second electrode layer 23R, and the first insulating layer 24R in this order, and at least one or more sub-pixels 20R are arranged in a light emitting region 200. The wiring connection portion 26 is formed outside the pixel region. In FIG. 10, the wiring connection portion 26 has a rectangular shape, but the shape of the wiring connection portion 26 is not particularly limited. The wiring connection portion 26 may be formed so as to surround the light emitting region 200. The sub-pixel of the other color (the sub-pixel 20G and/or 20B) is also formed in the light emitting region 200. Note that the light emitting device 2 may include, outside the light emitting region 200, an electrode pad for external connection used for a connection with an external circuit.

### (2-3) Step of Forming Second Insulating Layer

Next, as in the first embodiment, after a second insulating layer 25R is formed, etch back is performed. With this, as shown in FIG. 9I, the second insulating layer 25R can be left on the side surfaces of the element constituting layer 22R, the second electrode layer 23R, and the first insulating layer 24R. In other words, the second insulating layer 25R is removed except the portion on the side surfaces of the element constituting layer 22R, the second electrode layer 23R, and the first insulating layer 24R. In this manner, the second insulating layer 25R having moisture resistance and gas permeation resistance is used as the side wall covering the side surface (end portion) of the element constituting layer 22R. With this, during a wet process such as photolithography in a subsequent step, which is performed under air atmosphere, it is possible to suppress permeation of oxygen and water (liquid) into the element constituting layer 22R. Accordingly, it is possible to manufacture the light emitting device 2 with suppressed deterioration of the light emitting element.

### (2-4) Step of Forming Second Light Emitting Element and Third Light Emitting Element

Next, as shown in FIGS. 9J, 9K and 9L, an element constituting layer 22G, a second electrode layer 23G, and a first insulating layer 24G are formed on the entire surface of the substrate 10. Then, as shown in FIGS. 9M and 9N, similar to the sub-pixel 20R, the element constituting layer 22G, the second electrode layer 23G, and the first insulating layer 24G are patterned by photolithography to remove a resist layer as shown in FIG. 9O. After a second insulating layer 25G is formed, etch back is performed. With this, as shown in FIG. 9P, the second insulating layer 25G can be left on the side surfaces of the element constituting layer 22G, the second electrode layer 23G, and the first insulating layer 24G. By performing similar steps for the sub-pixel 20B, as shown in FIG. 9P, a second insulating layer 25B can be left on the side surfaces of an element constituting layer 22B, the second electrode layer 23B, and the first insulating layer 24B. FIG. 9P schematically shows the section of the light emitting device 2 after patterning of each of the sub-pixels 20R, 20G, and 20B is completed.

### (2-5) Step of Patterning First Insulating Layer

Next, as shown in FIG. 9Q, the first insulating layers 24R, 24G, and 24B are patterned using photolithography, thereby forming contact holes 28R, 28G, and 28B for the sub-pixels 20R, 20G, and 20B, respectively.

### (2-6) Step of Forming Third Electrode Layer

Next, as shown in FIG. 9R, the third electrode layer 27 is formed on the entire surface of the substrate 10, thereby electrically connecting the wiring connection portion 26 to the second electrode layers 23R, 23G, and 23B. Then, by performing exposure, development, etching, and resist peeling by using photolithography, as shown in FIG. 9S, the third electrode layer 27 existing in an unnecessary portion is removed.

### (2-7) Sealing Step

After patterning the third electrode layer 27, the light emitting element and wiring connection portion 26 forming the light emitting device 2 are sealed by a glass cap or a sealing thin film made of an inorganic material. In this embodiment, as shown in FIG. 9T, the sealing layer 30 as a sealing thin film made of an inorganic material is formed on the third electrode layer 27 and the first insulating layers 24R, 24G, and 24B. As the constituent material of the sealing layer 30, an inorganic material having high moisture resistance, for example, silicon nitride, silicon oxide (SiO), aluminum oxide (AlO), or the like can be used. Note that the material itself and composition ratio of the sealing layer 30 are not particularly limited as long as sealing by the thin film is possible. As a method of forming the sealing layer 30, a Chemical Vapor Deposition method (CVD) or an Atom Layer Deposition method (ALD) can be used, but the method is not limited to these methods.

In this embodiment, after the sealing layer 30 is formed, patterning of the sealing layer 30 may be performed to expose an electrode pad (external connection terminal) for external connection used for a connection with an external circuit. The end portions of the element constituting layers 22R, 22G, and 22B, the second electrode layers 23R, 23G, and 23B, and the first insulating layers 24R, 24G, and 24B are preferably covered with the sealing layer 30. With this, it is possible to further prevent permeation of water and oxygen from the end portions of the element constituting layers 22R, 22G, and 22B, so that the durability of the element forming the light emitting device 2 can be further improved.

Application examples in which the light emitting device 1 or 2 according to the embodiment is applied to an image forming device, a display device, a photoelectric conversion device, an electronic apparatus, an illumination device, a moving body, and a wearable device will be described below. Here, a description will be given assuming that the light emitting pixel 20 of the light emitting device 1 or 2 is, for example, an organic light emitting element such as an organic EL. Details of each component arranged in the light emitting pixel 20 of the light emitting device 1 or 2 will be described first, and the application examples will be described after that.

### <Arrangement of Organic Light Emitting Element>

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case in which a planarizing layer is provided between the color filter and the microlens.

### <Substrate> (Substrate 10)

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The material of the insulating layer is not limited as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### <Electrode> (First Electrode Layer 21, Second Electrode Layer 23)

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them can be used. As the constituent material of the anode, a metal oxide such as tin oxide, zinc oxide, indium oxide, indium tin oxide (ITO), or zinc indium oxide can also be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The materials as described above can function as a reflective film having no role as an electrode. If a transparent electrode is used as the electrode, an oxide transparent conductive layer made of indium tin oxide (ITO), indium zinc oxide, or the like can be used, but the present invention is not limited thereto. Note that a photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### <Pixel Isolation Layer> (Pixel Isolation Film 11)

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer is adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by a dark spot, a conductive failure of the second electrode, or the like can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce leakage of charges to an adjacent pixel. The film thickness of the pixel isolation layer may be 10 nm (inclusive) to 150 nm (inclusive). A similar effect can be obtained in an arrangement including only pixel electrodes without the pixel isolation layer. In this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

<Organic Compound Layer> (Element Constituting Layer 22)

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### <Protection Layer>

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 m by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method.

The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### <Color Filter>

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### <Planarizing Layer>

A planarizing layer may be provided between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### <Microlens>

The organic light emitting device may include an optical member such as a microlens on the light emission side. The microlens is made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. Accordingly, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface on the opposite side of the first surface. The second surface is arranged on the functional layer (light emitting layer) side of the first surface. In order to implement this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### <Counter Substrate>

A counter substrate may be arranged on the planarizing layer. The counter substrate is called a counter substrate because it is provided at a position corresponding to the above-described substrate. The constituent material of the counter substrate can be the same as that of the above-described substrate.

### <Organic Layer>

The organic compound layer (hole injection layer, hole transport layer, electron blocking layer, light emitting layer, hole blocking layer, electron transport layer, electron injection layer, and the like) forming the organic light emitting element in the embodiment may be formed by the method to be described below.

The organic compound layer forming the organic light emitting element in the embodiment can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### <Pixel Circuit>

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### <Pixel>

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any shape known in the art. For example, a quadrangle such as a rectangle or a rhombus, a hexagon, or the like may be possible. Note that a shape which is not a correct shape but is close to a rectangle is included in a rectangle, as a matter of course. The shape of the sub-pixel and the pixel arrangement can be used in combination.

### <Application of Organic Light Emitting Element in Embodiment>

The organic light emitting element in the embodiment can be used as a constituent member of a display device or an illumination device. In addition, the organic light emitting element in the embodiment can also be used in the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

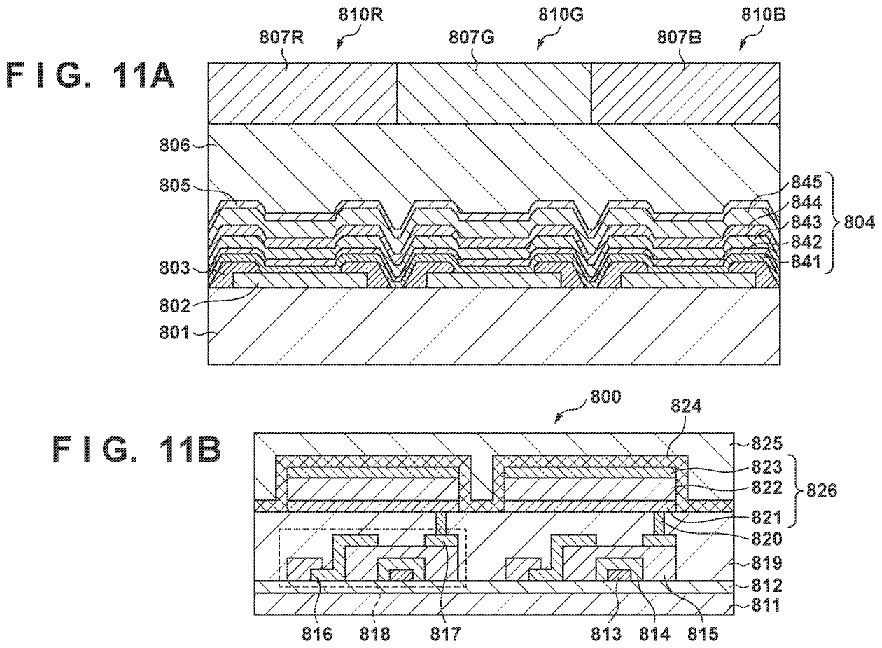

More details will be described next with reference to the accompanying drawings. FIG. 11A shows an example of the pixel described above. The pixel includes sub-pixels 810. The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. The sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 is also called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer 806 may include a single layer or a plurality of layers. Each layer can be an inorganic compound layer or an organic compound layer.

The color filter 807 is divided into color filters 807R, 807G, and 807B by colors. The color filters 807 may be formed on a planarizing film (not shown). A resin protection layer (not shown) may be arranged on the color filters 807. The color filters 807 may be formed on the protection layer 806. Alternatively, the color filters 807 may be provided on the counter substrate such as a glass substrate, and then the substrate may be bonded.

As shown in FIG. 11B, a display device 800 includes an organic light emitting element 826 and a TFT 818 as an example of a transistor. An insulating layer 812 is provided on a substrate 811 of glass, silicon, or the like. The active element such as the TFT 818 is arranged on the insulating layer 812, and a gate electrode 813, a gate insulating film 814, and a semiconductor layer 815 forming the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film 819.

A method of electrically connecting the electrodes (anode and cathode) included in the organic light emitting element 826 and the electrodes (source electrode and drain electrode) included in the TFT is not limited to that shown in FIG. 11B. One of the anode and cathode of the organic light emitting element 826 and one of the source electrode and drain electrode of the TFT are electrically connected. The TFT means a thin-film transistor.

In the display device 800 shown in FIG. 11B, an organic compound layer 822 is illustrated as one layer. However, the organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 11B, but another switching element may be used in place of the transistor.

The transistor used in the display device 800 shown in FIG. 11B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 11B may be formed in the substrate such as a silicon substrate. Forming the transistor in the substrate means forming the transistor by processing the substrate such as a silicon substrate. In other words, when the transistor is included in the substrate, this means that the substrate and the transistor are formed integrally.

The light emission luminance of the organic light emitting element in the embodiment can be controlled by the TFT which is an example of a switching element, and the plurality of organic light emitting elements can be provided in a plane to display an image with the light emission luminances of the respective elements. Here, the switching element in the embodiment is not limited to the TFT, and may be a transistor formed from low-temperature polysilicon or an active matrix driver formed on the substrate such as a silicon substrate. Note that the term “on the substrate” also means “in the substrate”. Whether to provide a transistor in the substrate or use a TFT is selected based on the size of the display unit. For example, if the size is about 0.5 inch, the organic light emitting element is preferably provided on the silicon substrate.

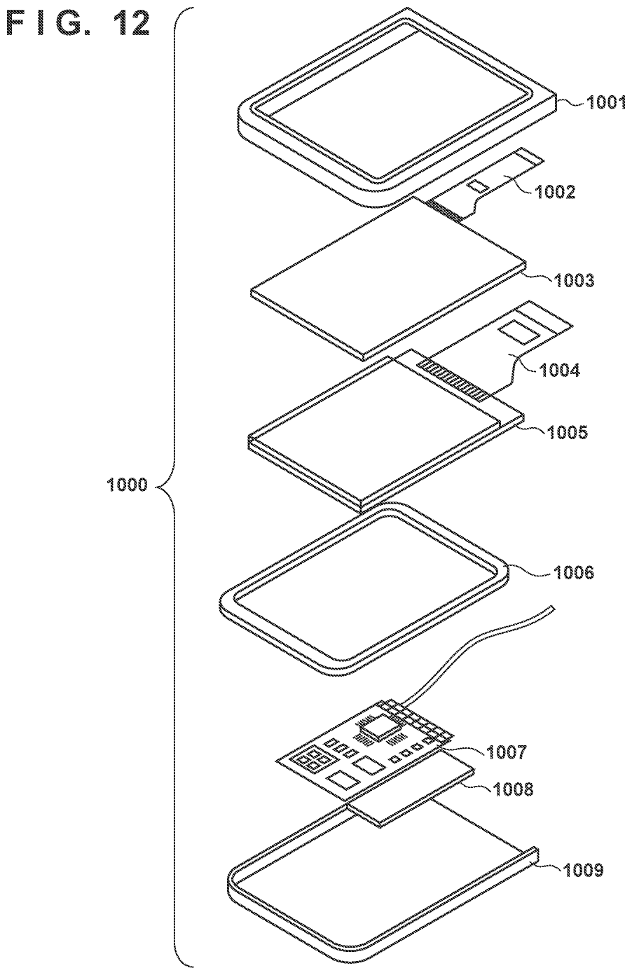

FIG. 12 is a view schematically showing an example of a display device 1000 using the light emitting device 1 or 2 in the embodiment. The display device 1000 includes an upper cover 1001 and a lower cover 1009, and further includes a touch panel 1003, a display panel 1005, a frame 1006, a circuit board 1007, and a battery 1008 between the upper cover 1001 and the lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. If the display device 1000 is a portable apparatus, the battery 1008 may be provided at a position different from the illustrated position. The light emitting device 1 or 2 is applied to the display panel 1005. The light emitting device 1 or 2 functioning as the display panel 1005 operates in a state in which it is connected to the active element such as a transistor arranged on the circuit board 1007.

The display device 1000 shown in FIG. 12 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

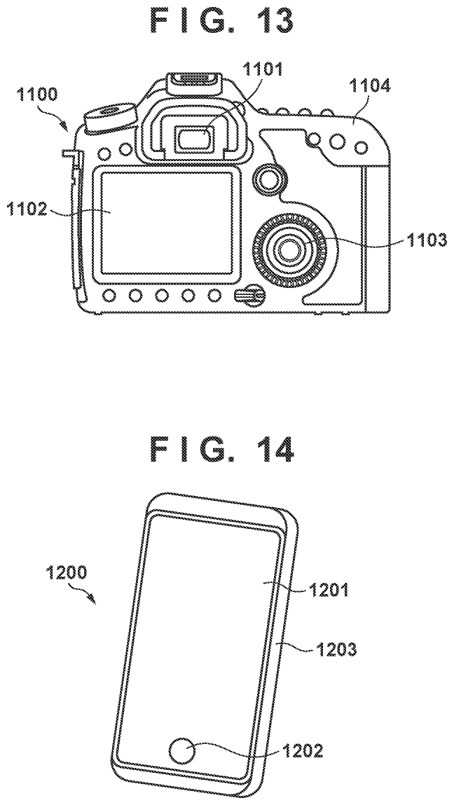

FIG. 13 is a view schematically showing an example of a photoelectric conversion device 1100 using the light emitting device 1 or 2 in the embodiment. The photoelectric conversion device 1100 includes a viewfinder 1101, a rear display 1102, an operation unit 1103, and a housing 1104. The photoelectric conversion device 1100 is also called an image capturing device. The light emitting device 1 or 2 in the embodiment is applied to the viewfinder 1101 or the rear display 1102 serving as a display unit. In this case, the light emitting device 1 or 2 may display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information is preferably displayed as soon as possible. Therefore, the light emitting device 1 or 2 formed by the pixel including the light emitting element using the organic light emitting material such as an organic EL element is preferable for the viewfinder 1101 or the rear display 1102. The organic light emitting material has a high response speed. The light emitting device 1 or 2 using the organic light emitting material is preferable for the devices that require a high display speed, and more suitable than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. The operation regarding focal point adjustment can also automatically be performed.

The light emitting device 1 or 2 may be applied to a display unit of an electronic apparatus such as a portable terminal. At this time, the display unit may have both a display function and an operation function. Examples of the portable terminal are a portable phone such as a smartphone, a tablet, and a head mounted display.

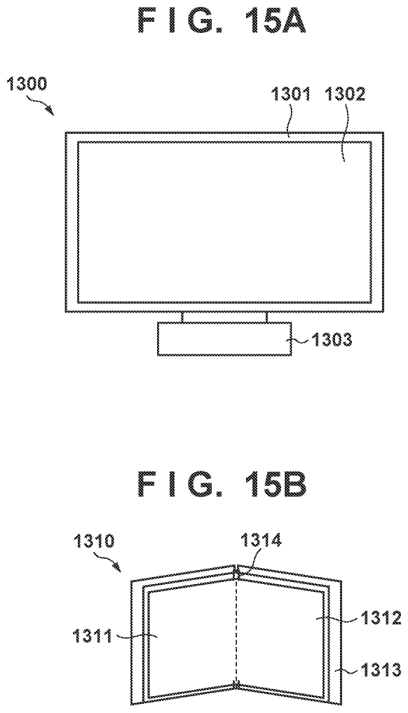

FIG. 14 is a view schematically showing an example of an electronic apparatus using the light emitting device 1 or 2 in the embodiment. An electronic apparatus 1200 includes a display unit 1201, an operation unit 1202, and a housing 1203. The housing 1203 may be provided with a circuit, a printed board having this circuit, a battery, a communication unit, and the like. The operation unit 1202 can be a button or a touch-panel-type reaction unit. The operation unit 1202 can also be a biometric authentication unit that performs unlocking or the like by authenticating the fingerprint. The portable apparatus including the communication unit can also be called a communication apparatus. The light emitting device 1 or 2 in the embodiment is applied to the display unit 1201.

FIGS. 15A and 15B are views schematically showing examples of the display device using the light emitting device 1 or 2 in the embodiment. FIG. 15A shows a display device 1300 such as a television monitor or a PC monitor. The display device 1300 includes a frame 1301 and a display unit 1302. The light emitting device 1 or 2 in the embodiment is applied to the display unit 1302. The display device 1300 may include a base 1303 that supports the frame 1301 and the display unit 1302. The base 1303 is not limited to the form shown in FIG. 15A. For example, the lower side of the frame 1301 may also function as the base 1303. In addition, the frame 1301 and the display unit 1302 may be formed by a curved surface. The radius of curvature in this case is, for example, 5,000 mm (inclusive) to 6,000 mm (inclusive).

FIG. 15B is a view schematically showing another example of the display device using the light emitting device 1 or 2 in the embodiment. A display device 1310 shown in FIG. 15B is a display device formed to be foldable, which is a so-called foldable display device. The display device 1310 includes a first display unit 1311, a second display unit 1312, a housing 1313, and a bending point 1314. The light emitting device 1 or 2 in the embodiment is applied to each of the first display unit 1311 and the second display unit 1312. The first display unit 1311 and the second display unit 1312 may also be one seamless display device. The first display unit 1311 and the second display unit 1312 can be divided by the bending point 1314. The first display unit 1311 and the second display unit 1312 may display different images, or may display one image together.

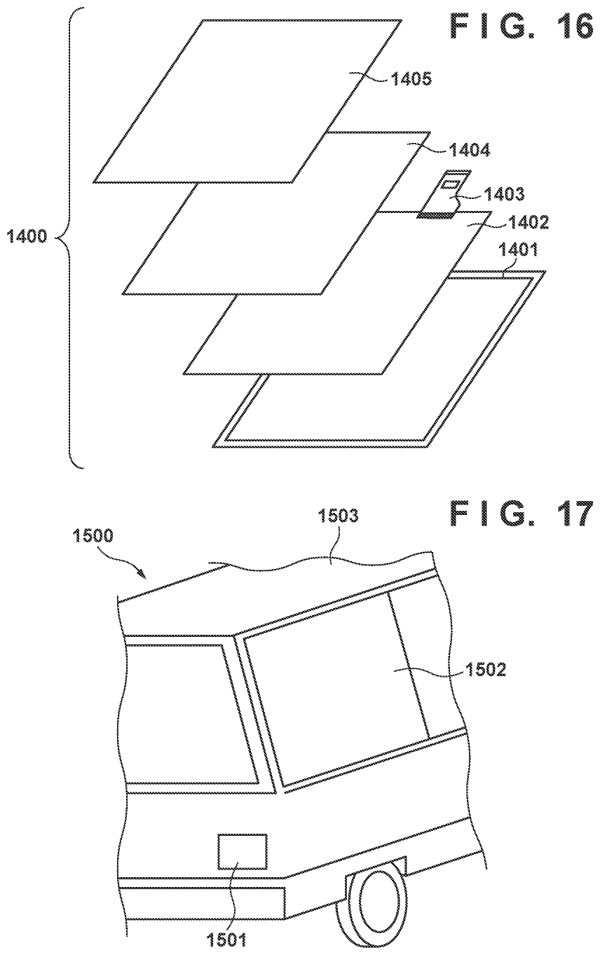

FIG. 16 is a view schematically showing an example of an illumination device 1400 using the light emitting device 1 or 2 in the embodiment. The illumination device 1400 includes a housing 1401, a light source 1402, a circuit board 1403, an optical film 1404, and a light diffusion unit 1405. The light emitting device 1 or 2 in the embodiment is applied to the light source 1402. The optical film 1404 may be a filter that improves the color rendering property of the light source. The light diffusion unit 1405 can effectively diffuse light from the light source to illuminate a wide range for lighting up or the like. A cover may be provided in the outermost portion of the illumination device 1400, as needed. The illumination device 1400 may include both the optical film 1404 and the light diffusion unit 1405, or may include only one of the optical film 1404 and the light diffusion unit 1405.

The illumination device 1400 is, for example, a device that illuminates a room. The illumination device 1400 may emit light of white, day white, or any other color from blue to red. The illumination device 1400 may include a light control circuit for controlling the light color. The illumination device 1400 may include a power supply circuit connected to the light emitting device 1 or 2 which functions as the light source 1402. The power supply circuit is a circuit that converts an AC voltage into a DC voltage. Note that white light has a color temperature of 4200K, and day-white light has a color temperature of 5000K. The illumination device 1400 may also include a color filter. Further, the illumination device 1400 may include a heat dissipation portion. The heat dissipation portion releases the heat in the device to the outside of the device, and examples thereof include a metal having high specific heat, liquid silicon, and the like.

FIG. 17 is a view schematically showing an automobile including a tail lamp which is an example of the lighting unit for an automobile using the light emitting device 1 or 2 in the embodiment. An automobile 1500 includes a tail lamp 1501, and turns on the tail lamp 1501, for example, when a brake operation or the like is performed. The light emitting device 1 or 2 in the embodiment may be used in a head lamp as the lighting unit for an automobile. The automobile 1500 is an example of a moving body, and the moving body includes a ship, a drone, an aircraft, a railroad car, an industrial robot, and the like. The moving body includes a body and a lighting unit provided in the body. The lighting unit may inform the current position of the body.

The light emitting device 1 or 2 in the embodiment is applied to the tail lamp 1501. The tail lamp 1501 may include a protective member that protects the light emitting device 1 or 2 which functions as the tail lamp 1501. The protective member has a certain degree of strength. The material of the protective member is not limited as long as it is transparent. For example, the protective member is made from polycarbonate or the like. The protective member may be made from a material obtained by mixing polycarbonate with furandicarboxylic acid derivative, acrylonitrile derivative, or the like.

The automobile 1500 includes a body 1503 and windows 1502 attached to the body 1503. The window 1502 may be a window for checking the front or rear of the automobile 1500, or may a transparent display such as a head-up display. The light emitting device 1 or 2 in the embodiment may be used for the transparent display. In this case, the components such as the electrodes included in the light emitting device 1 or 2 are formed by transparent members.

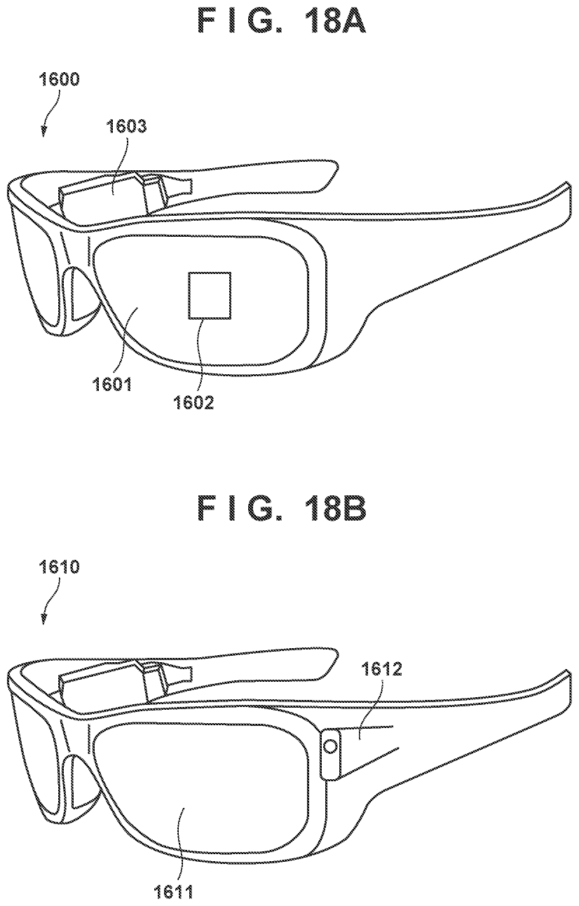

Further application examples of the light emitting device 1 or 2 in the embodiment will be described with reference to FIGS. 18A and 18B. The light emitting device 1 or 2 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

FIG. 18A is a view schematically showing glasses 1600 (smartglasses) in one application example. An image capturing device 1602 such as a CMOS sensor or an SPAD is provided on the surface side of a lens 1601 of the glasses 1600. In addition, the light emitting device 1 or 2 in the embodiment is provided on the back surface side of the lens 1601.

The glasses 1600 further include a control device 1603. The control device 1603 functions as a power supply that supplies electric power to the image capturing device 1602 and the light emitting device 1 or 2. In addition, the control device 1603 controls the operations of the image capturing device 1602 and the light emitting device 1 or 2. An optical system configured to condense light to the image capturing device 1602 is provided on the lens 1601.

FIG. 18B is a view schematically showing glasses 1610 (smartglasses) according to one application example. The glasses 1610 include a control device 1612, and an image capturing device corresponding to the image capturing device 1602 and the light emitting device 1 or 2 are mounted on the control device 1612. The lens 1611 is provided with the image capturing device mounted in the control device 1612, and an optical system configured to project light emitted from the light emitting device 1 or 2, and an image is projected to the lens 1611. The control device 1612 functions as a power supply that supplies electric power to the image capturing device and the light emitting device 1 or 2, and controls the operations of the image capturing device and the light emitting device 1 or 2. The control device 1612 may include a line-of-sight detection unit that detects the line of sight of a wearer (user). The detection of a line of sight of the wearer may be done using infrared rays. An infrared ray emitting unit emits infrared rays to an eyeball of the wearer who is gazing at a displayed image. An image capturing unit including a light receiving element detects reflected light from the eyeball, thereby obtaining a captured image of the eyeball. A reduction unit for reducing light from the infrared ray emitting unit to the display unit in a planar view is provided, thereby reducing deterioration of image quality.

The line of sight of the wearer to the displayed image is detected from the captured image of the eyeball obtained by capturing the infrared rays. A method known in the art can be applied to the line-of-sight detection using the captured image of the eyeball. For example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the wearer.

In this embodiment, an image capturing device including a light receiving element may be included, and a displayed image may be controlled based on the line-of-sight information of the wearer from the image capturing device.

More specifically, a first visual field region at which the user is gazing and a second visual field region other than the first visual field region are decided based on the line-of-sight information. The first visual field region and the second visual field region may be decided by the control device, or those decided by an external control device may be received. In the display region, the display resolution of the first visual field region may be controlled to be higher than the display resolution of the second visual field region. In other words, the resolution of the second visual field region may be lower than that of the first visual field region.

In addition, the display region includes a first display region and a second display region different from the first display region, and a region of higher priority is decided from the first display region and the second display region based on line-of-sight information. The region of higher priority may be decided by the control device, or those decided by an external control device may be received. The resolution of the region of higher priority may be controlled to be higher than the resolution of the region other than the region of higher priority. In other words, the resolution of the region of relatively low priority may be low.

Note that AI may be used to decide the first visual field region or the region of higher priority. The AI is a model configured to estimate the angle of the line of sight and the distance to a target ahead the line of sight from the image of the eyeball using, for example, the image of the eyeball and the direction of actual viewing of the eyeball included in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can be applied. The smartglasses can display captured outside information in real time.

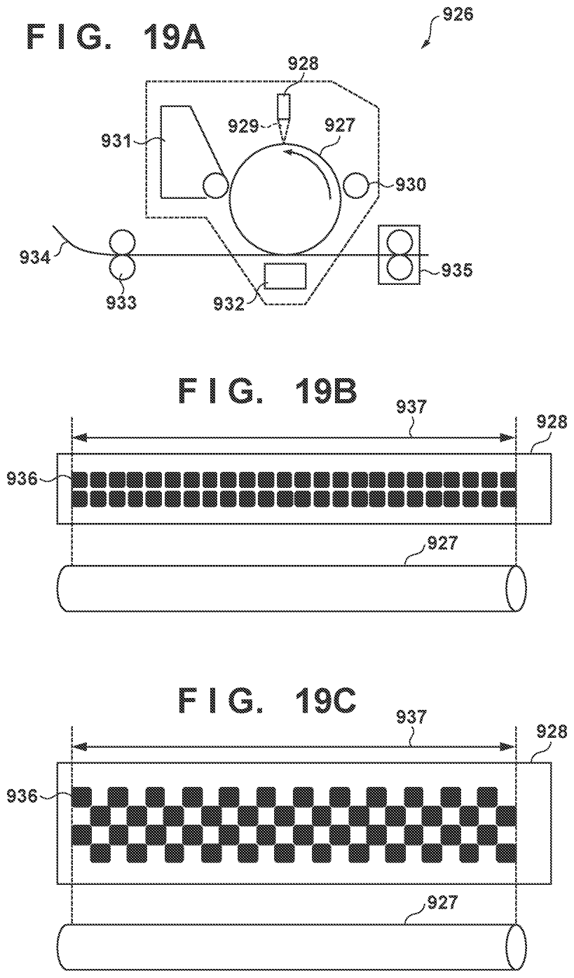

FIGS. 19A to 19C are views schematically showing an example of an image forming device 926 using the light emitting device 1 or 2 in the embodiment. The image forming device 926 shown in FIG. 19A includes a photosensitive member 927, an exposure light source 928, a developing unit 931, a charging unit 930, a transfer device 932, a conveyance unit 933 (a conveyance roller shown in FIG. 19A), and a fixing device 935.

Light 929 is emitted from the exposure light source 928, and an electrostatic latent image is formed on the surface of the photosensitive member 927. The light emitting device 1 or 2 in the embodiment is applied to the exposure light source 928. The developing unit 931 functions as a developing device that contains a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 includes, for example, paper or a film. The fixing device 935 fixes the image formed on the print medium 934.

Each of FIGS. 19B and 19C is a view schematically showing a plurality of light emitting units 936 arranged along the longitudinal direction on a long substrate in the exposure light source 928. The light emitting device 1 or 2 in the embodiment is applied to the light emitting units 936. For example, the plurality of pixels of the light emitting device 1 or 2 are arrayed along the longitudinal direction of the substrate. A direction 937 is a direction parallel to the axis of the photosensitive member 927. This column direction matches the direction of the axis upon rotating the photosensitive member 927. This direction 937 can be referred to as the long-axis direction of the photosensitive member 927.

FIG. 19B shows a form in which the light emitting units 936 are arranged along the long-axis direction of the photosensitive member 927. FIG. 19C shows a modification of the arrangement of the light emitting units 936 shown in FIG. 19B, and shows a form in which the light emitting units 936 are arranged in the column direction alternately between the first column and the second column. The light emitting units 936 are arranged at different positions in the row direction between the first column and the second column. In the first column, multiple light emitting units 936 are arranged spaced apart from each other. In the second column, the light emitting unit 936 is arranged at the position corresponding to the space between the light emitting units 936 in the first column. Also in the row direction, multiple light emitting units 936 are arranged spaced apart from each other. It can also be said that the arrangement of the light emitting units 936 shown in FIG. 19C is, for example, an arrangement in a grid pattern, an arrangement in a staggered pattern, or an arrangement in a checkered pattern.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-033074 filed on Mar. 3, 2023, which is hereby incorporated by reference herein in its entirety.

What is claimed is:

1. A method of manufacturing a light emitting device, the method comprising:
forming a resist layer on the first insulating layer so as to expose a part of the first insulating layer in a region, the second electrode layer being on an element constituting layer including a light-emitting layer that is arranged on a first electrode;
removing the first insulating layer, the second electrode layer, and the element constituting layer in the region;
removing the resist layer after removing the first insulating layer, the second electrode layer, and the element constituting layer;
forming a side wall including an insulating material, which covers side surfaces of the first insulating layer, the second electrode layer, and the element constituting layer, after removing the resist layer; and
forming a contact hole in the first insulating layer on the second electrode layer after forming the side wall.

2. The method according to claim 1, wherein
the forming the side wall includes
forming a second insulating layer including the insulating material on the first insulating layer and the region where the first insulating layer, the second electrode layer, and the element constituting layer have been removed, and
removing the second insulating layer expect a portion on the side surfaces of the first insulating layer, the second electrode layer, and the element constituting layer.

3. The method according to claim 1, wherein
in the forming the contact hole, the contact hole is formed in the first insulating layer by photolithography.

4. The method according to claim 1, further comprising forming a third electrode layer configured to connect the second electrode layer and an electrode via the contact hole.

5. The method according to claim 4, wherein
in the forming the third electrode layer, the third electrode layer is formed such that the third electrode layer is electrically connected to the side surface of at least the second electrode layer.

6. The method according to claim 1, wherein
the second electrode layer is a stacked body formed by a plurality of layers.

7. The method according to claim 1, wherein
the first insulating layer is a stacked body formed by a plurality of layers.

8. The method according to claim 1, further comprising forming a hard mask layer on the first insulating layer before forming the resist layer,
wherein
in the forming the resist layer, the resist layer is formed on the hard mask layer by patterning the hard mask layer by photolithography, and
in the removing the first insulating layer, the second electrode layer, and the element constituting layer, the first insulating layer, the second electrode layer, and the element constituting layer are removed by etching using the hard mask layer as a mask.

9. The method according to claim 1, wherein
the light emitting device includes a plurality of pixels each including the element constituting layer,
in the forming the side wall, for each of the plurality of pixels, the side wall is formed on side surfaces of the first insulating layer, the second electrode layer, and the element constituting layer, and
in the forming the contact hole, for each of the plurality of pixels, the contact hole is formed in the first insulating layer on the second electrode layer after the side wall is formed on the side surfaces of the first insulating layer, the second electrode layer, and the element constituting layer.

10. The method according to claim 9, wherein
the plurality of pixels include at least pixels of not less than two different colors.
